(19) United States
(12) Patent Application Publication
(10) Pub. No.: US 2026/0082690 A1
(43) Pub. Date: Mar. 19, 2026

(54) SEMICONDUCTOR DEVICE

(71) Applicant: Samsung Electronics Co., Ltd., Suwon-si (KR)

(72) Inventors: Jeong Hyeon Lee, Suwon-si (KR); Min Seok Jo, Suwon-si (KR); Hyung Koo Kang, Suwon-si (KR); Jong Han Lee, Suwon-si (KR)

(21) Appl. No.: 19/194,099

(22) Filed: Apr. 30, 2025

(30) Foreign Application Priority Data
Sep. 19, 2024 (KR) 10-2024-0126480

(51) Int. Cl. H10D 84/83; H10D 30/00; H10D 30/01; H10D 30/43; H10D 62/10; H10D 62/13; H10D 64/23; H10D 64/27; H10D 84/01

(52) U.S. Cl. CPC H10D 84/832; H10D 30/43; H10D 30/502; H10D 62/121; H10D 62/151; H10D 64/256; H10D 64/514; H10D 64/518; H10D 30/014; H10D 30/0191; H10D 84/0153

(57) ABSTRACT

A semiconductor device includes a lower interlayer insulating layer, an insulating pattern extending in a first direction on the lower interlayer insulating layer, a plurality of nanosheets on the insulating pattern and spaced apart in a third direction, an active cut penetrating the lower interlayer insulating layer, the insulating pattern and the plurality of nanosheets, the active cut extending in a second direction and comprising an upper surface extending between opposing first and second sidewalls, and a first gate electrode extending in the second direction on the insulating pattern, wherein the first gate electrode includes a first portion in contact with the first sidewall of the active cut in the second direction, a second portion in contact with the upper surface of the active cut, and a third portion in contact with the second sidewall of the active cut, where the second connects the first portion and the third portion.

### CROSS-REFERENCE TO RELATED APPLICATION

This application claims priority from Korean Patent Application No. 10-2024-0126480 filed on Sep. 19, 2024, in the Korean Intellectual Property Office, and all the benefits accruing therefrom under 35 U.S.C. 119, the contents of which in its entirety are herein incorporated by reference.

### TECHNICAL FIELD

The present disclosure relates to a semiconductor device. More particularly, the present disclosure relates to a semiconductor device including a MBCFET™ (Multi-Bridge Channel Field Effect Transistor).

### BACKGROUND

As one of the scaling techniques to increase the density of integrated circuit devices, multi-gate transistors have been proposed, in which a fin-shaped or nanowire-shaped silicon body is formed on a substrate, and gates are formed on the surface of the silicon body.

Since these multi-gate transistors utilize a three-dimensional channel, they may be easy to scale. Additionally, the current control capability may be improved without increasing the gate length of the multi-gate transistor. Furthermore, the SCE (short channel effect), in which the potential of the channel region is influenced by the drain voltage, may be effectively suppressed.

### SUMMARY

The present disclosure provides a semiconductor device that enhances integration density by electrically connecting adjacent gate electrodes using a portion of the gate electrodes disposed on the upper surface of the active cut.

The embodiments of the present disclosure are not limited to those mentioned above and another embodiment which is not mentioned may be clearly understood by those skilled in the art from the description below.

According to some embodiments of the present disclosure, there is provided a semiconductor device, including a lower interlayer insulating layer, an insulating pattern on the lower interlayer insulating layer and extending in a first direction, the first direction parallel to an upper surface of the lower interlayer insulating layer and crossing a second direction parallel that is to the upper surface of the lower interlayer insulating layer, a plurality of nanosheets on the insulating pattern and spaced apart from each other in a third direction that is perpendicular to the upper surface of the lower interlayer insulating layer, an active cut penetrating the lower interlayer insulating layer, the insulating pattern and the plurality of nanosheets in the third direction, the active cut extending in the second direction and comprising an upper surface extending between opposing first and second sidewalls, and a first gate electrode extending in the second direction on the insulating pattern, the first gate electrode at least partially surrounding the plurality of nanosheets, wherein the first gate electrode includes a first portion in contact with the first sidewall of the active cut in the second direction, a second portion in contact with the upper surface of the active cut, the second portion at least partially surrounding the plurality of nanosheets, and a third portion in contact with the second sidewall of the active cut in the second direction, and wherein the second portion of the first gate electrode connects the first portion of the first gate electrode and the third portion of the first gate electrode.

According to some embodiments of the present disclosure, there is provided a semiconductor device, including a lower interlayer insulating layer, an insulating pattern on the lower interlayer insulating layer and extending in a first direction that is parallel to an upper surface of the lower interlayer insulating layer, a first gate electrode on the insulating pattern and extending in a second direction that is parallel to the upper surface of the lower interlayer insulating layer and crosses from the first direction, a second gate electrode extending in the second direction on the insulating pattern, the second gate electrode spaced apart from the first gate electrode in the first direction, a third gate electrode extending in the second direction on the insulating pattern, the third gate electrode spaced apart from the second gate electrode in the first direction, a first gate cut extending in the first direction on the lower interlayer insulating layer, the first gate cut spaced apart from the insulating pattern in the second direction, the first gate cut penetrating the first gate electrode in the second direction, a second gate cut extending in the first direction on the lower interlayer insulating layer, the second gate cut spaced apart from the insulating pattern in the second direction, the second gate cut spaced apart from the first gate cut in the first direction, the second gate cut penetrating the third gate electrode in the second direction, and an active cut penetrating the lower interlayer insulating layer and the insulating pattern in a third direction perpendicular to the upper surface of the lower interlayer insulating layer, the active cut extending in the second direction beneath the second gate electrode and comprising an upper surface extending between opposing first and second sidewalls, the upper surface of the active cut in contact with the second gate electrode, at least a portion of the active cut between the first gate cut and the second gate cut, wherein the second gate electrode includes a first portion in contact with the first sidewall of the active cut in the second direction, a second portion in contact with the upper surface of the active cut, and, a third portion in contact with the second sidewall of the active cut in the second direction, and wherein the second portion of the second gate electrode connects the first portion of the second gate electrode and the third portion of the second gate electrode.

According to some embodiments of the present disclosure, there is provided a semiconductor device, comprising a lower interlayer insulating layer, an insulating pattern extending in a first direction that is parallel to an upper surface of the lower interlayer insulating layer and crosses a second direction that is parallel to the upper surface of the lower interlayer insulating layer, a plurality of nanosheets stacked on the insulating pattern spaced apart from each other in a third direction that is perpendicular to the upper surface of the lower interlayer insulating layer, a first gate electrode extending in the second direction on the insulating pattern, a second gate electrode extending in the second direction on the insulating pattern, the second gate electrode spaced apart from the first gate electrode in the first direction, the second gate electrode at least partially surrounding the plurality of nanosheets, a third gate electrode extending in the second direction on the insulating pattern, the third gate electrode spaced apart from the second gate electrode in the first direction, a source/drain region between the second and third gate electrodes on the insulating pattern, a bottom source/drain contact penetrating the lower interlayer insulating layer and the insulating pattern in the third direction, the bottom source/drain contact electrically connected to the source/drain region, a first gate cut extending in the first direction on the lower interlayer insulating layer, the first gate cut spaced apart from the insulating pattern in the second direction, the first gate cut penetrating the first gate electrode in the second direction, a second gate cut extending in the first direction on the lower interlayer insulating layer, the second gate cut spaced apart from the insulating pattern in the second direction, the second gate cut spaced apart from the first gate cut in the first direction, the second gate cut penetrating the third gate electrode in the second direction, an active cut penetrating the lower interlayer insulating layer, the insulating pattern and the plurality of nanosheets in the third direction, the active cut extending in the second direction beneath the second gate electrode and comprising an upper surface extending between opposing first and second sidewalls, at least a portion of the active cut between the first gate cut and the second gate cut, wherein the upper surface of the active cut is higher than an upper surface of an uppermost nanosheet of the plurality of nanosheets, relative to the lower interlayer insulating layer, and a capping pattern in contact with an upper surface of the second gate electrode, the capping pattern spaced apart from the upper surface of the active cut in the third direction, wherein the second gate electrode includes a first portion in contact with the first sidewall of the active cut in the second direction, a second portion in contact with the upper surface of the active cut, the second portion at least partially surrounding the plurality of nanosheets, and a third portion being in contact with the second sidewall of the active cut in the second direction, and wherein the second portion of the second gate electrode connects the first portion of the second gate electrode and the third portion of the second gate electrode.

### BRIEF DESCRIPTION OF THE DRAWINGS

The above and other aspects and features of the present disclosure will become more apparent by describing in detail embodiments thereof with reference to the attached drawings, in which:

FIG. 1 is a layout diagram for explaining a semiconductor device according to some embodiments of the present disclosure;

FIG. 2 is a cross-sectional view taken along the line A-A′ of FIG. 1;

FIG. 3 is a cross-sectional view taken along the line B-B′ of FIG. 1;

FIG. 4 is a cross-sectional view taken along the line C-C′ of FIG. 1;

FIG. 5 is a cross-sectional view taken along the line D-D′ of FIG. 1;

FIGS. 6 to 39 are intermediate stage diagrams for explaining a fabrication method of a semiconductor device according to some embodiments of the present disclosure;

FIG. 40 is a cross-sectional view for explaining a semiconductor device according to some other embodiments of the present disclosure;

FIGS. 41 and 42 are cross-sectional views for explaining a semiconductor device according to other several embodiments of the present disclosure;

FIG. 43 is a layout diagram for explaining a semiconductor device according to some other embodiments of the present disclosure;

FIG. 44 is a layout diagram for explaining a semiconductor device according to another several embodiments of the present disclosure;

FIG. 45 is a cross-sectional view taken along the line E-E′ of FIG. 44;

FIG. 46 is a layout diagram for explaining a semiconductor device according to another several embodiments of the present disclosure; and

FIG. 47 is a cross-sectional view taken along the line F-F′ of FIG. 46.

### DETAILED DESCRIPTION OF EMBODIMENTS

In the following diagrams of a semiconductor device according to some embodiments, the semiconductor device is described as including, by way of example, a transistor (MBCFET™ (Multi-Bridge Channel Field Effect Transistor)) that includes nanosheets, but the present disclosure is not limited thereto. In some other embodiments, the semiconductor device may include a fin-shaped transistor (FinFET) having a channel region in a fin-shaped pattern, a tunneling transistor (tunneling FET), or a three-dimensional (3D) transistor. In addition, the semiconductor device according to some other embodiments may include a bipolar junction transistor or a lateral double-diffused metal-oxide-semiconductor (LDMOS) transistor.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” as may be used herein may not require completely surrounding or covering or filling the described elements or layers, but may, for example, refer to partially surrounding or covering or filling the described elements or layers, for example, with voids or other spaces throughout. The term “exposed,” may be used to describe relationships between elements and/or certain intermediate processes in fabricating a completed semiconductor device, but may not necessarily require exposure of the particular region, layer, structure or other element in the context of the completed device.

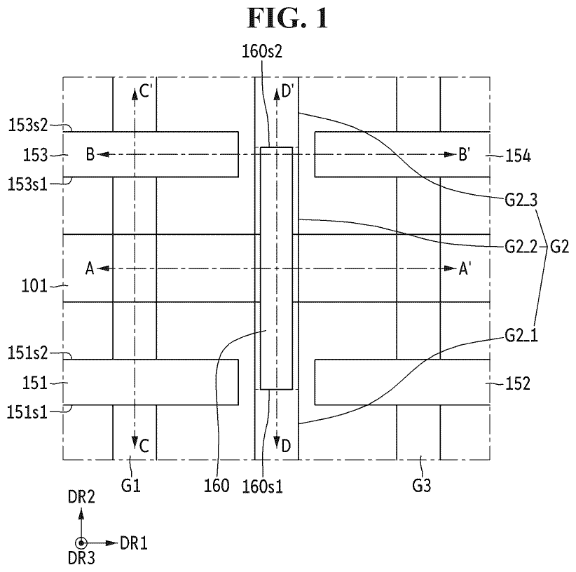

Hereinafter, a semiconductor device according to some embodiments of the present disclosure will be described with reference to FIGS. 1 to 5.

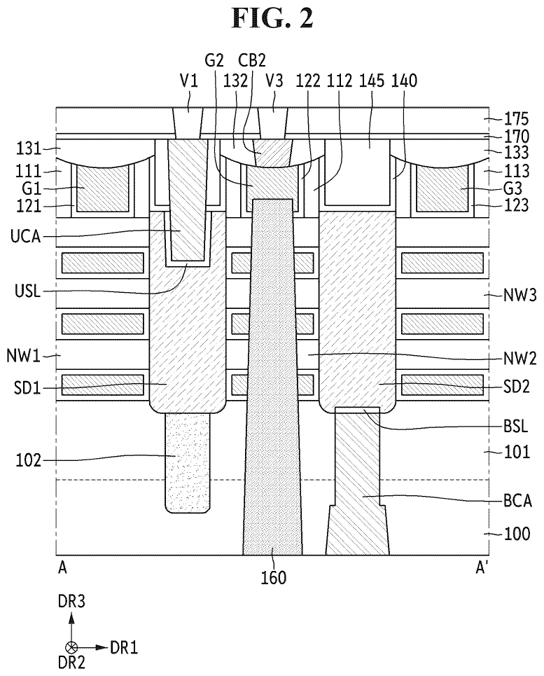

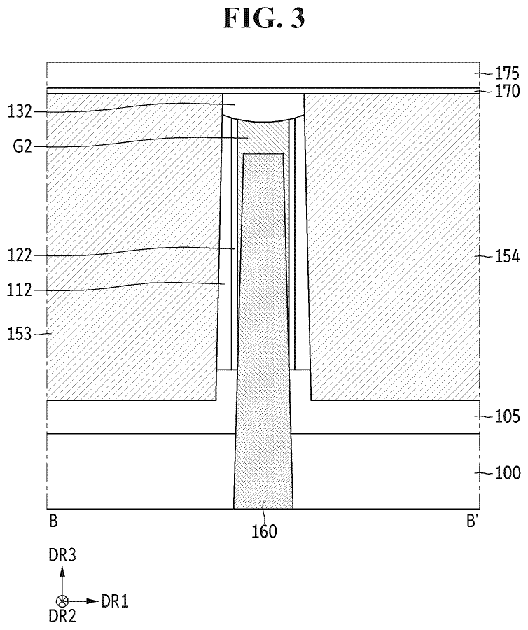

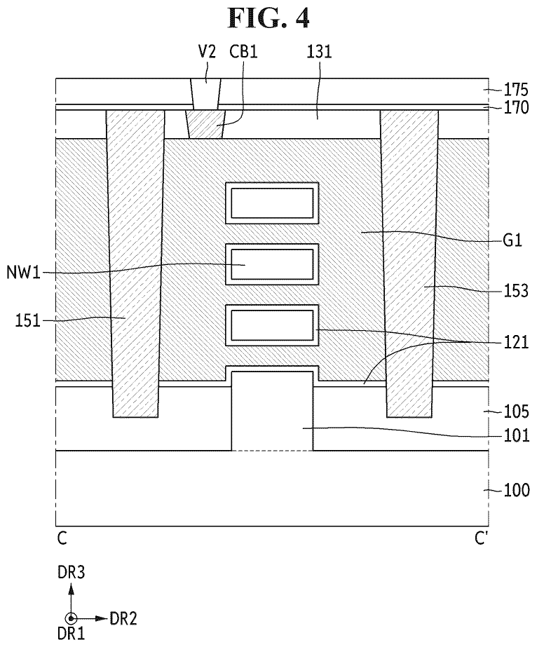

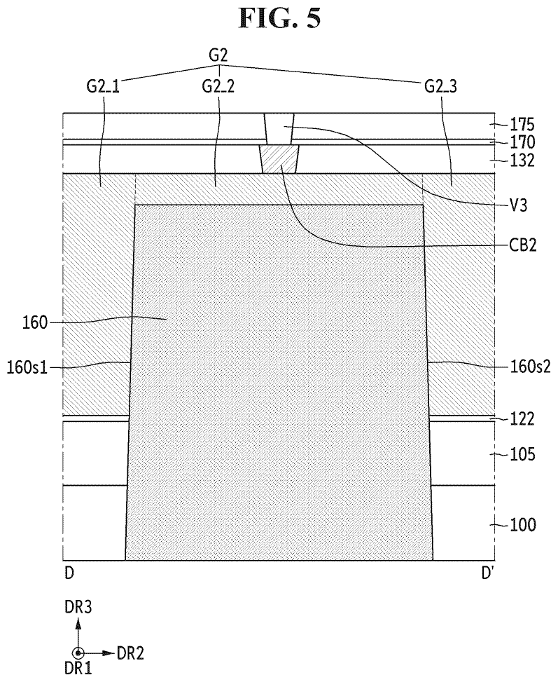

FIG. 1 is a layout diagram for explaining a semiconductor device according to some embodiments of the present disclosure. FIG. 2 is a cross-sectional view taken along the line A-A′ of FIG. 1. FIG. 3 is a cross-sectional view taken along the line B-B′ of FIG. 1. FIG. 4 is a cross-sectional view taken along the line C-C′ of FIG. 1. FIG. 5 is a cross-sectional view taken along the line D-D′ of FIG. 1.

Referring to FIGS. 1 to 5, a semiconductor device according to some embodiments of the present disclosure includes a lower interlayer insulating layer 100, an insulating pattern 101, a first sacrificial pattern 102, a field insulating layer 105, first to third plurality of nanosheets NW1, NW2, NW3, first to third gate electrodes G1, G2, G3, first to third gate spacers 111, 112, 113, first to third gate insulating layers 121, 122, 123, first to third capping patterns 131, 132, 133, first and second source/drain regions SD1, SD2, a first etching stop layer 140, a first upper interlayer insulating layer 145, first to fourth gate cuts 151, 152, 153, 154, an active cut 160, an upper source/drain contact UCA, a bottom source/drain contact BCA, an upper silicide layer USL, a bottom silicide layer BSL, first and second gate contacts CB1, CB2, a second etching stop layer 170, a second upper interlayer insulating layer 175, and first to third vias V1, V2, V3. A cut region (or “cut”), as used herein, may refer to a portion of a structure that is removed and subsequently replaced by a non-conductive material.

The lower interlayer insulating layer 100 may include, for example, at least one of silicon oxide, silicon nitride, silicon oxynitride, and a low-k dielectric material. The low-k dielectric material may include, for example, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, and/or combinations thereof, but the present disclosure is not limited thereto.

Hereinafter, each of the first horizontal direction DR1 and the second horizontal direction DR2 may be defined as a direction parallel to the upper surface of the lower interlayer insulating layer 100. The second horizontal direction DR2 may be defined as a direction different from (e.g., crossing or intersecting) the first horizontal direction DR1. The vertical direction DR3 may be defined as a direction perpendicular to each of the first horizontal direction DR1 and the second horizontal direction DR2. In other words, the vertical direction DR3 may be defined as a direction perpendicular to the upper surface of the lower interlayer insulating layer 100.

The insulating pattern 101 may extend in the first horizontal direction DR1 on the upper surface of the lower interlayer insulating layer 100. The insulating pattern 101 may protrude in the vertical direction DR3 from the upper surface of the lower interlayer insulating layer 100. The bottom surface of the insulating pattern 101 may be in contact with the upper surface of the lower interlayer insulating layer 100. The insulating pattern 101 may include insulating materials. For example, the insulating pattern 101 may include the same material as the lower interlayer insulating layer 100.

The field insulating layer 105 may be disposed on the upper surface of the lower interlayer insulating layer 100. The field insulating layer 105 may surround the sidewalls of the insulating pattern 101. For example, the upper surface of the insulating pattern 101 may protrude in the vertical direction DR3 beyond the upper surface of the field insulating layer 105. However, the present disclosure is not limited thereto. In some other embodiments, the upper surface of the insulating pattern 101 may be formed on the same plane as (i.e., may be coplanar with) the upper surface of the field insulating layer 105. The field insulating layer 105 may include, for example, an oxide layer, a nitride layer, an oxynitride layer, or a combination thereof.

Each of the first to third plurality of nanosheets NW1, NW2, NW3 may be disposed on the insulating pattern 101. The second plurality of nanosheets NW2 may be spaced apart from the first plurality of nanosheets NW1 in the first horizontal direction DR1. The third plurality of nanosheets NW3 may be spaced apart from the second plurality of nanosheets NW2 in the first horizontal direction DR1. Each of the first to third plurality of nanosheets NW1, NW2, NW3 may include a plurality of nanosheets stacked and spaced apart from each other in the vertical direction DR3 on the insulating pattern. In FIGS. 1 and 3, each of the first to third plurality of nanosheets NW1, NW2, NW3 is shown as including three nanosheets stacked and spaced apart from each other in the vertical direction DR3, but this is for convenience of explanation and is not limited to the technical ideas of the present disclosure. In some other embodiments, each of the first to third plurality of nanosheets NW1, NW2, NW3 may include four or more nanosheets stacked and spaced apart from each other in the vertical direction DR3. For example, each of the first to third plurality of nanosheets NW1, NW2, NW3 may include silicon (Si). However, the present disclosure is not limited thereto. In some other embodiments, each of the first to third plurality of nanosheets NW1, NW2, NW3 may include silicon germanium (SiGe).

The first gate electrode G1 may extend in the second horizontal direction DR2 on the insulating pattern 101 and the field insulating layer 105. The first gate electrode G1 may surround the first plurality of nanosheets NW1. The second gate electrode G2 may extend in the second horizontal direction DR2 on the insulating pattern 101 and the field insulating layer 105. The second gate electrode G2 may be spaced apart from the first gate electrode G1 in the first horizontal direction DR1. The second gate electrode G2 may surround the second plurality of nanosheets NW2. The third gate electrode G3 may extend in the second horizontal direction DR2 on the insulating pattern 101 and the field insulating layer 105. The third gate electrode G3 may be spaced apart from the second gate electrode G2 in the first horizontal direction DR1. The third gate electrode G3 may surround the third plurality of nanosheets NW3.

The second gate electrode G2 may include a first portion G2_1, a second portion G2_2, and a third portion G2_3. For example, the second portion G2_2 of the second gate electrode G2 may surround the second plurality of nanosheets NW2. The second portion G2_2 of the second gate electrode G2 may include a first sidewall and a second sidewall in the second horizontal direction DR2. The second sidewall of the second portion G2_2 of the second gate electrode G2 may be opposite to the first sidewall of the second portion G2_2 of the second gate electrode G2 in the second horizontal direction DR2. The first portion G2_1 of the second gate electrode G2 may be in contact with the first sidewall of the second portion G2_2 of the second gate electrode G2 in the second horizontal direction DR2. The third portion G2_3 of the second gate electrode G2 may be in contact with the second sidewall of the second portion G2_2 of the second gate electrode G2 in the second horizontal direction DR2. That is, the second portion G2_2 of the second gate electrode G2 may be connected the first portion G2_1 of the second gate electrode G2 and the third portion G2_3 of the second gate electrode G2.

For example, each of the first to third gate electrodes G1, G2, G3 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first to third gate electrodes G1, G2, G3 may include a conductive metal oxide, and/or a conductive metal oxynitride, etc., and may also include the oxidized form of the aforementioned materials.

The first gate spacer 111 may extend in the second horizontal direction DR2 along opposing sidewalls of the first gate electrode G1 on the upper surface of the uppermost nanosheet of the first plurality of nanosheets NW1 and the field insulating layer 105. The second gate spacer 112 may extend in the second horizontal direction DR2 along opposing sidewalls of the second gate electrode G2 on the upper surface of the uppermost nanosheet of the second plurality of nanosheets NW2 and the field insulating layer 105. The third gate spacer 113 may extend in the second horizontal direction DR2 along opposing sidewalls of the third gate electrode G3 on the upper surface of the uppermost nanosheet of the third plurality of nanosheets NW3 and the field insulating layer 105. For example, each of the first to third gate spacers 111, 112, 113 may include at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof. However, the present disclosure is not limited thereto.

The first source/drain region SD1 may be disposed between the first gate electrode G1 and the second gate electrode G2 on the insulating pattern 101. The first source/drain region SD1 may be in contact with the sidewalls in the first horizontal direction DR1 of each of the first and second plurality of nanosheets NW1, NW2. The second source/drain region SD2 may be disposed between the second gate electrode G2 and the third gate electrode G3 on the insulating pattern 101. The second source/drain region SD2 may be in contact with the sidewalls in the first horizontal direction DR1 of each of the second and third plurality of nanosheets NW2, NW3. For example, the upper surface of each of the first and second source/drain regions SD1, SD2 may be formed higher than the upper surfaces of the uppermost nanosheets of each of the first and third plurality of nanosheets NW1, NW2, NW3.

The first sacrificial pattern 102 may be disposed beneath the first source/drain region SD1. Spatially relative terms such as “above,” “upper,” “upper portion,” “upper surface,” “below,” “beneath,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. The first sacrificial pattern 102 may be in contact with the bottom surface of the first source/drain region SD1. The first sacrificial pattern 102 may penetrate the insulating pattern 101 in the vertical direction DR3. For example, the lower interlayer insulating layer 100 may cover the bottom surface of the first sacrificial pattern 102. For example, opposing sidewalls of the first sacrificial pattern 102 in the first horizontal direction DR1 may be in contact with each of the lower interlayer insulating layer 100 and the insulating pattern 101. The first sacrificial pattern 102 may include a material different from that of the lower interlayer insulating layer 100 and the insulating pattern 101, respectively. For example, the first sacrificial pattern 102 may include silicon germanium (SiGe).

The first gate insulating layer 121 may be disposed between the first gate electrode G1 and the insulating pattern 101. The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the first source/drain region SD1.

The second gate insulating layer 122 may be disposed between the second gate electrode G2 and the insulating pattern 101. The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the first source/drain region SD1. The second gate insulating layer 122 may be disposed between the second gate electrode G2 and the second source/drain region SD2.

The third gate insulating layer 123 may be disposed between the third gate electrode G3 and the insulating pattern 101. The third gate insulating layer 123 may be disposed between the third gate electrode G3 and the field insulating layer 105. The third gate insulating layer 123 may be disposed between the third gate electrode G3 and the third gate spacer 113. The third gate insulating layer 123 may be disposed between the third gate electrode G3 and the third plurality of nanosheets NW3. The third gate insulating layer 123 may be disposed between the third gate electrode G3 and the second source/drain region SD2.

For example, each of the first to third gate insulating layers 121, 122, 123 may include at least one of silicon oxide, silicon oxynitride, silicon nitride, or a high-k dielectric material with a dielectric constant greater than that of silicon oxide. High-k dielectric materials may include, for example, one or more of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments may include an NC (Negative Capacitance) FET utilizing a negative capacitor. For example, each of the first to third gate insulating layers 121, 122, 123 may include a ferroelectric material layer having ferroelectric properties and a paraelectric material layer having paraelectric properties.

The ferroelectric material layer may have a negative capacitance, while the paraelectric material layer may have a positive capacitance. For example, when two or more capacitors are connected in series and each of their capacitances has a positive value, the overall capacitance is reduced compared to the capacitance of each individual capacitor. On the other hand, if at least one of the capacitances of the two or more capacitors connected in series has a negative value, the overall capacitance may be greater than the absolute value of each individual capacitance while still being positive.

When the ferroelectric material layer having a negative capacitance and the paraelectric material layer having a positive capacitance are connected in series, the overall capacitance value of the ferroelectric material layer and the paraelectric material layer connected in series may increase. By utilizing the increase in overall capacitance value, the transistor including the ferroelectric material layer may have a subthreshold swing (SS) of less than 60 mV/decade at room temperature.

The ferroelectric material layer may have ferroelectric properties. The ferroelectric material layer may include, for example, at least one of hafnium oxide, hafnium zirconium oxide, barium strontium titanium oxide, barium titanium oxide, and/or lead zirconium titanium oxide. As another example, hafnium zirconium oxide may be a material in which zirconium (Zr) is doped into hafnium oxide. In another example, hafnium zirconium oxide may be a compound of hafnium (Hf) and zirconium (Zr) with oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). Depending on which ferroelectric material the ferroelectric material layer contains, the type of dopant contained in the ferroelectric material layer may vary.

When the ferroelectric material layer includes hafnium oxide, the dopant included in the ferroelectric material layer may include, for example, at least one of gadolinium (Gd), silicon (Si), zirconium (Zr), aluminum (Al), and/or yttrium (Y).

If the dopant is aluminum (Al), the ferroelectric material layer may contain 3 to 8 at % (atomic %) of aluminum. Here, the ratio of the dopant may be a ratio of aluminum to the sum of hafnium and aluminum.

If the dopant is silicon (Si), the ferroelectric material layer may include 2 to 10 at % of silicon. If the dopant is yttrium (Y), the ferroelectric material layer may include 2 to 10 at % of yttrium. If the dopant is gadolinium (Gd), the ferroelectric material layer may include 1 to 7 at % of gadolinium. If the dopant is zirconium (Zr), the ferroelectric material layer may include 50 to 80 at % of zirconium.

The paraelectric material layer may have paraelectric properties. The paraelectric material layer may include, for example, at least one of silicon oxide and a high-k metal oxide. The metal oxide included in the paraelectric material layer may include, for example, at least one of hafnium oxide, zirconium oxide, and/or aluminum oxide, but is not limited thereto.

The ferroelectric material layer and the paraelectric material layer may include the same material. While the ferroelectric material layer may have ferroelectric properties, the paraelectric material layer may not have ferroelectric properties. For example, when the ferroelectric material layer and the paraelectric material layer include hafnium oxide, the crystal structure of the hafnium oxide included in the ferroelectric material layer is different from the crystal structure of the hafnium oxide included in the paraelectric material layer.

The ferroelectric material layer may have a thickness having ferroelectric properties. The thickness of the ferroelectric material layer may be, for example, 0.5 to 10 nm, but is not limited thereto. Since each ferroelectric material may have a different critical thickness for exhibiting ferroelectric properties, the thickness of the ferroelectric material layer may vary depending on the specific ferroelectric material.

For example, each of the first to third gate insulating layers 121, 122, 123 may include a single ferroelectric material layer. In another example, each of the first to third gate insulating layers 121, 122, 123 may include a plurality of ferroelectric material layers spaced apart from each other. Each of the first to third gate insulating layers 121, 122, 123 may have a stacked layer structure in which the plurality of ferroelectric material layers are alternately stacked with the plurality of paraelectric material layers.

The first etching stop layer 140 may be disposed on the sidewalls of each of the first to third gate spacers 111, 112, 113 in the first horizontal direction DR1. The first etching stop layer 140 may be disposed on the upper surfaces of each of the first and second source/drain regions SD1, SD2. Although not shown, the first etching stop layer 140 may be disposed on the sidewalls of each of the first and second source/drain regions SD1, SD2 in the second horizontal direction DR2. For example, the first etching stop layer 140 may be conformally formed. The first etching stop layer 140 may include, for example, at least one of aluminum oxide, aluminum nitride, hafnium oxide, zirconium oxide, silicon oxide, silicon nitride, silicon oxynitride, and/or a low-k dielectric material.

The first capping pattern 131 may extend in the second horizontal direction DR2 on each of the first gate spacer 111, the first gate insulating layer 121, and the first gate electrode G1. The first capping pattern 131 may be in contact with the upper surface of the first gate electrode G1. The second capping pattern 132 may extend in the second horizontal direction DR2 on each of the second gate spacer 112, the second gate insulating layer 122, and the second gate electrode G2. The second capping pattern 132 may be in contact with the upper surface of the second gate electrode G2. The third capping pattern 133 may extend in the second horizontal direction DR2 on each of the third gate spacer 113, the third gate insulating layer 123, and the third gate electrode G3. The third capping pattern 133 may be in contact with the upper surface of the third gate electrode G3.

For example, the upper surfaces of each of the first to third capping patterns 131, 132, 133 may be formed on the same plane. For example, the bottom surface of the first capping pattern 131 may be in contact with the upper surface of the first gate spacer 111. The bottom surface of the second capping pattern 132 may be in contact with the upper surface of the second gate spacer 112. The bottom surface of the third capping pattern 133 may be in contact with the upper surface of the third gate spacer 113. For example, the bottom surfaces of each of the first to third capping patterns 131, 132, 133 may be in contact with the first etching stop layer 140. However, the present disclosure is not intended to be limited thereto. In some other embodiments, the sidewalls of each of the first to third capping patterns 131, 132, 133 may be in contact with the first etching stop layer 140. For example, each of the first to third capping patterns 131, 132, 133 may include insulating materials. Each of the first to third capping patterns 131, 132, 133 may include, for example, at least one of silicon nitride (SiN), silicon oxynitride (SiON), silicon oxide (SiO₂), silicon carbonitride (SiCN), silicon oxycarbonitride (SiOCN), and/or combinations thereof.

The first upper interlayer insulating layer 145 may be disposed on the first etching stop layer 140. The first upper interlayer insulating layer 145 may be disposed on the sidewalls of each of the first to third capping patterns 131, 132, 133. The first upper interlayer insulating layer 145 may cover each of the first and second source/drain regions SD1, SD2 on the field insulating layer 105. For example, the upper surface of the first upper interlayer insulating layer 145 may be formed on the same plane as the upper surfaces of each of the first to third capping patterns 131, 132, 133. However, the present disclosure is not limited thereto. In some other embodiments, the first upper interlayer insulating layer 145 may cover the upper surfaces of each of the first to third capping patterns 131, 132, 133. The first upper interlayer insulating layer 145 may include, for example, at least one of silicon oxide, silicon nitride, silicon oxynitride, and/or a low-k dielectric material.

Each of the first and second gate cuts 151, 152 may extend in the first horizontal direction DR1 on the lower interlayer insulating layer 100. The insulating pattern 101 may be spaced apart from each of the first and second gate cuts 151, 152 in the second horizontal direction DR2. The second gate cut 152 may be spaced apart from the first gate cut 151 in the first horizontal direction DR1. For example, the first gate cut 151 may separate the first gate electrode G1 in the second horizontal direction DR2. The second gate cut 152 may separate the third gate electrode G3 in the second horizontal direction DR2.

Each of the third and fourth gate cuts 153, 154 may extend in the first horizontal direction DR1 on the lower interlayer insulating layer 100. Each of the third and fourth gate cuts 153, 154 may be spaced apart from the insulating pattern 101 in the second horizontal direction DR2. That is, the insulating pattern 101 may be disposed between the first gate cut 151 and the third gate cut 153. Additionally, the insulating pattern 101 may be disposed between the second gate cut 152 and the fourth gate cut 154. The fourth gate cut 154 may be spaced apart from the third gate cut 153 in the first horizontal direction DR1. For example, the third gate cut 153 may separate the first gate electrode G1 in the second horizontal direction DR2. The fourth gate cut 154 may separate the third gate electrode G3 in the second horizontal direction DR2.

For example, each of the first and third gate cuts 151, 153 may penetrate the first capping pattern 131, the first gate electrode G1, the first gate spacer 111, and the first gate insulating layer 121 in the vertical direction DR3 to be extended into the inside of the field insulating layer 105. Each of the second and fourth gate cuts 152, 154 may penetrate the third capping pattern 133, the third gate electrode G3, the third gate spacer 113, and the third gate insulating layer 123 in the vertical direction DR3 to be extended into the inside of the field insulating layer 105. For example, the upper surfaces of each of the first to fourth gate cuts 151, 152, 153, 154 may be formed on the same plane as the upper surfaces of each of the first to third capping patterns 131, 132, 133. For example, the sidewalls of each of the first to fourth gate cuts 151, 152, 153, 154 in the first horizontal direction DR1 may be in contact with each of the second gate spacer 112 and the second capping pattern 132. However, the present disclosure is not limited thereto.

For example, each of the first to fourth gate cuts 151, 152, 153, 154 does not intersect with the second gate electrode G2. That is, each of the first to fourth gate cuts 151, 152, 153, 154 is not in contact with the second gate electrode G2. For example, each of the first and second gate cuts 151, 152 may overlap with at least a portion of the first portion G2_1 of the second gate electrode G2 in the first horizontal direction DR1. Additionally, each of the first and second gate cuts 151, 152 may overlap with at least a portion of the second portion G2_2 of the second gate electrode G2 in the first horizontal direction DR1.

For example, each of the third and fourth gate cuts 153, 154 may overlap with at least a portion of the second portion G2_2 of the second gate electrode G2 in the first horizontal direction DR1. Additionally, each of the third and fourth gate cuts 153, 154 may overlap with at least a portion of the third portion G2_3 of the second gate electrode G2 in the first horizontal direction DR1.

For example, the first gate cut 151 may include a first sidewall 151s1 and a second sidewall 151s2 opposite the first sidewall 151s1 in the second horizontal direction DR2. The second sidewall 151s2 of the first gate cut 151 may face the insulating pattern 101. For example, the interface between the first portion G2_1 of the second gate electrode G2 and the second portion G2_2 of the second gate electrode G2 may be formed between the first sidewall 151s1 of the first gate cut 151 and the second sidewall 151s2 of the first gate cut 151. That is, each of the first and second gate cuts 151, 152 may overlap with the interface between the first portion G2_1 of the second gate electrode G2 and the second portion G2_2 of the second gate electrode G2 in the first horizontal direction DR1.

For example, the third gate cut 153 may include a first sidewall 153s1 and a second sidewall 153s2 opposite the first sidewall 153s1 in the second horizontal direction DR2. The first sidewall 153s1 of the third gate cut 153 may face the insulating pattern 101. For example, the interface between the second portion G2_2 of the second gate electrode G2 and the third portion G2_3 of the second gate electrode G2 may be formed between the first sidewall 153s1 of the third gate cut 153 and the second sidewall 153s2 of the third gate cut 153. In other words, each of the third and fourth gate cuts 153, 154 may overlap with the interface between the second portion G2_2 of the second gate electrode G2 and the third portion G2_3 of the second gate electrode G2 in the first horizontal direction DR1.

Each of the first to fourth gate cuts 151, 152, 153, 154 may include insulating materials. For example, each of the first to fourth gate cuts 151, 152, 153, 154 may include at least one of silicon nitride (SiN), silicon oxynitride (SiON), silicon carbonitride (SiCN), silicon oxycarbonitride (SiOCN), silicon boron nitride (SiBN), silicon oxyboron nitride (SiOBN), silicon oxycarbide (SiOC), and/or combinations thereof. However, the present disclosure is not limited thereto.

The active cut 160 may extend in the second horizontal direction DR2 beneath the second gate electrode G2. For example, the active cut 160 may penetrate each of the lower interlayer insulating layer 100, the insulating pattern 101, the field insulating layer 105, and the second plurality of nanosheets NW2 in the vertical direction DR3. For example, the upper surface of the active cut 160 may be formed higher than the upper surface of the uppermost nanosheet of the second plurality of nanosheets NW2, relative to the lower interlayer insulating layer 100. For example, the upper surface of the active cut 160 may be in contact with the second gate electrode G2. Specifically, the upper surface of the active cut 160 may be in contact with the second portion (G2_2) of the second gate electrode G2. For example, the bottom surface of the second capping pattern 132 may be spaced apart from the upper surface of the active cut 160 in the vertical direction DR3. That is, the second capping pattern 132 is not in contact with the upper surface of the active cut 160.

For example, on the upper surface of the uppermost nanosheet of the second plurality of nanosheets NW2, the sidewall of the active cut 160 in the first horizontal direction DR1 may be in contact with the second gate electrode G2. Specifically, on the upper surface of the uppermost nanosheet of the second plurality of nanosheets NW2, the sidewall of the active cut 160 in the first horizontal direction DR1 may be in contact with the second portion G2_2 of the second gate electrode G2. For example, on the upper surface of the uppermost nanosheet of the second plurality of nanosheets NW2, the sidewall of the active cut 160 in the first horizontal direction DR1 may be in contact with the second gate insulating layer 122.

For example, between the upper surface of the insulating pattern 101 and the bottom surface of the lowermost nanosheet of the second plurality of nanosheets NW2, the second gate electrode G2 may be in contact with opposing sidewalls of the active cut 160 in the first horizontal direction DR1. Additionally, between adjacent ones of the second plurality of nanosheets NW2, the second gate electrode G2 may be in contact with opposing sidewalls of the active cut 160 in the first horizontal direction DR1. For example, between the upper surface of the insulating pattern 101 and the bottom surface of the lowermost nanosheet of the second plurality of nanosheets NW2, the second gate insulating layer 122 may be in contact with opposing sidewalls of the active cut 160 in the first horizontal direction DR1. Additionally, between adjacent ones of the second plurality of nanosheets NW2, the second gate insulating layer 122 may be in contact with opposing sidewalls of the active cut 160 in the first horizontal direction DR1.

For example, the sidewall of the active cut 160 in the first horizontal direction DR1 may be spaced apart from the second gate spacer 112 in the first horizontal direction DR1. However, the present disclosure is not limited thereto. In some other embodiments, the sidewall of the active cut 160 in the first horizontal direction DR1 may be in contact with the second gate spacer 112. For example, at least a portion of the second gate electrode G2 may be disposed between each of the first to fourth gate cuts 151, 152, 153, 154 and the active cut 160. For example, the second gate spacer 112 and the second gate insulating layer 122 may be disposed between each of the first to fourth gate cuts 151, 152, 153, 154 and the active cut 160.

For example, at least a portion of the active cut 160 may be disposed between the first gate cut 151 and the second gate cut 152. That is, at least a portion of the active cut 160 may overlap with each of the first and second gate cuts 151, 152 in the first horizontal direction DR1. For example, the active cut 160 may include a first sidewall 160s1 and a second sidewall 160s2 in the second horizontal direction DR2. The second sidewall 160s2 of the active cut 160 may be opposite to the first sidewall 160s1 of the active cut 160 in the second horizontal direction DR2. For example, the first sidewall 160s1 of the active cut 160 may overlap with each of the first and second gate cuts 151, 152 in the first horizontal direction DR1. That is, the first sidewall 160s1 of the active cut 160 may be formed at a position along the second direction DR2 that is between the first sidewall 151s1 of the first gate cut 151 and the second sidewall 151s2 of the first gate cut 151.

For example, at least a portion of the active cut 160 may be disposed between the third gate cut 153 and the fourth gate cut 154. That is, at least a portion of the active cut 160 may overlap with each of the third and fourth gate cuts 153, 154 in the first horizontal direction DR1. For example, the second sidewall 160s2 of the active cut 160 may overlap with each of the third and fourth gate cuts 153, 154 in the first horizontal direction DR1. That is, the second sidewall 160s2 of the active cut 160 may be formed at a position along the second direction DR2 that is between the first sidewall 153s1 of the third gate cut 153 and the second sidewall 153s2 of the third gate cut 153. For example, the first sidewall 160s1 of the active cut 160 may be in contact with the first portion G2_1 of the second gate electrode G2. The second sidewall 160s2 of the active cut 160 may be in contact with the third portion G2_3 of the second gate electrode G2.

For example, the active cut 160 may include insulating materials. For example, the active cut 160 may include at least one of silicon nitride (SiN), silicon oxynitride (SiON), silicon carbonitride (SiCN), silicon oxycarbonitride (SiOCN), silicon oxycarbide (SiOC), and/or combinations thereof. However, the present disclosure is not limited thereto.

The upper source/drain contact UCA may be disposed between the first gate electrode G1 and the second gate electrode G2. The upper source/drain contact UCA may be disposed over the first source/drain region SD1. The upper source/drain contact UCA may penetrate the first upper interlayer insulating layer 145 and the first etching stop layer 140 in the vertical direction DR3 to be extended into the inside of the first source/drain region SD1. The upper source/drain contact UCA may be electrically connected to the first source/drain region SD1. The upper surface of the upper source/drain contact UCA may be formed on the same plane as the upper surface of the first upper interlayer insulating layer 145. However, the present disclosure is not limited thereto. In some other embodiments, the upper surface of the upper source/drain contact UCA may be formed higher than the upper surface of the first upper interlayer insulating layer 145, relative to the lower interlayer insulating layer 100. The upper source/drain contact UCA may include conductive materials.

The bottom source/drain contact BCA may be disposed between the second gate electrode G2 and the third gate electrode G3. For example, the bottom source/drain contact BCA may be disposed between the active cut 160 and the third gate electrode G3. The bottom source/drain contact BCA may be spaced apart from the active cut 160 in the first horizontal direction DR1. The bottom source/drain contacts BCA may be disposed beneath the second source/drain region SD2. The bottom source/drain contact BCA may penetrate the lower interlayer insulating layer 100 and insulating pattern 101 in the vertical direction DR3 to be electrically connected to the second source/drain region SD2. For example, opposing sidewalls of the bottom source/drain contact BCA in the first horizontal direction DR1 may be in contact with each of the insulating pattern 101 and the lower interlayer insulating layer 100. For example, the bottom surface of the bottom source/drain contact BCA may be formed on the same plane as the bottom surface of the lower interlayer insulating layer 100. The bottom source/drain contact BCA may include conductive materials.

In some other embodiments, the source/drain contact connected to the first source/drain region SD1 may be disposed beneath the first source/drain region SD1. That is, the source/drain contact connected to the first source/drain region SD1 may be disposed beneath the first source/drain region SD1, and the source/drain contact connected to the second source/drain region SD2 may be disposed beneath the second source/drain region SD2. In some other embodiments, the source/drain contact connected to the second source/drain region SD2 may be disposed over the second source/drain region SD2. That is, the source/drain contacts connecting to the first source/drain region SD1 may be disposed over the first source/drain region SD1, and the source/drain contact connected to the second source/drain region SD2 may be disposed over the second source/drain region SD2.

The upper silicide layer USL may be disposed between the upper source/drain contact UCA and the first source/drain region SD1. The upper silicide layer USL may be disposed along the interface between the upper source/drain contact UCA and the first source/drain region SD1. The bottom silicide layer BSL may be disposed between the bottom source/drain contact BCA and the second source/drain region SD2. The bottom silicide layer BSL may be disposed along the interface between the bottom source/drain contact BCA and the second source/drain region SD2. For example, each of the upper silicide layer USL and the bottom silicide layer BSL may include metal silicide materials.

The first gate contact CB1 may penetrate the first capping pattern 131 in the vertical direction DR3 to be connected to the first gate electrode G1. The second gate contact CB2 may penetrate the second capping pattern 132 in the vertical direction DR3 to be connected to the second gate electrode G2. For example, the upper surfaces of each of the first and second gate contacts CB1, CB2 may be formed on the same plane as the upper surfaces of each of the first and second capping patterns 131, 132, but the present disclosure is not limited thereto. In some other embodiments, the upper surfaces of each of the first and second gate contacts CB1, CB2 may be formed higher than the upper surfaces of each of the first and second capping patterns 131, 132. Each of the first and second gate contacts CB1, CB2 may include conductive materials.

The second etching stop layer 170 may be disposed on the upper surfaces of each of the upper source/drain contact UCA, the first and second gate contacts CB1, CB2, the first to third capping patterns 131, 132, 133, and the first upper interlayer insulating layer 145. In FIGS. 2 to 5, the second etching stop layer 170 is shown as being formed as a single layer, but the present disclosure is not limited thereto. In some other embodiments, the second etching stop layer 170 may be formed as multiple layers. For example, the second etching stop layer 170 may include at least one of aluminum oxide, aluminum nitride, hafnium oxide, zirconium oxide, silicon oxide, silicon nitride, silicon oxynitride, and/or a low-k dielectric material. The second upper interlayer insulating layer 175 may be disposed on the second etching stop layer 170. The second upper interlayer insulating layer 175 may include at least one of, for example, silicon oxide, silicon nitride, silicon oxynitride, and/or a low-k dielectric material.

The first via V1 may penetrate the second upper interlayer insulating layer 175 and the second etching stop layer 170 in the vertical direction DR3 to be connected to the upper source/drain contact UCA. The second via V2 may penetrate the second upper interlayer insulating layer 175 and the second etching stop layer 170 in the vertical direction DR3 to be connected to the first gate contact CB1. The third via V3 may penetrate the second upper interlayer insulating layer 175 and the second etching stop layer 170 in the vertical direction DR3 to be connected to the second gate contact CB2. Each of the first to third vias V1, V2, V3 may include conductive materials.

In the semiconductor device according to some embodiments of the present disclosure, the active cut 160 may be disposed beneath the second gate electrode G2, and an upper surface of the active cut 160 may be in contact with the second portion G2_2 of the second gate electrode G2. That is, the active cut 160 may not extend completely through the second gate electrode G2, such that a second portion G2_2 extends along an upper surface of the active cut 160. The second portion G2_2 of the second gate electrode G2 disposed on the upper surface of the active cut 160 may connect the first portion G2_1 of the second gate electrode G2 and the third portion G2_3 of the second gate electrode G2. The second portion G2_2 of the second gate electrode G2 may function as a wiring that electrically connects the first portion G2_1 and the third portion G2_3 of the second gate electrode G2. The semiconductor device according to some embodiments of the present disclosure may enhance the integration density of the semiconductor device by utilizing a portion of the gate electrodes disposed on the upper surface of the active cut 160 to electrically connect adjacent gate electrodes, e.g., without forming additional wiring to electrically connect the first portion G2_1 and the third portion G2_3 of the gate electrode G2.

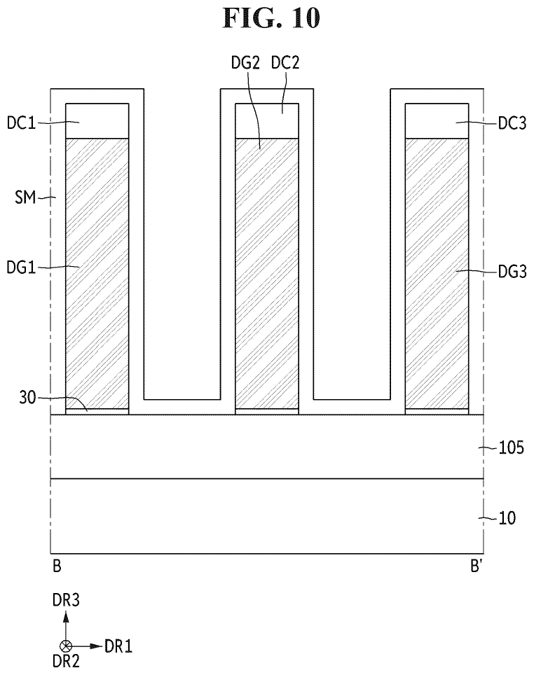

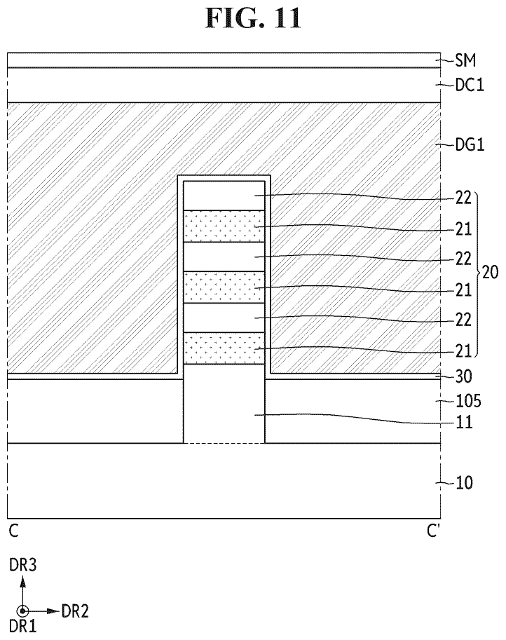

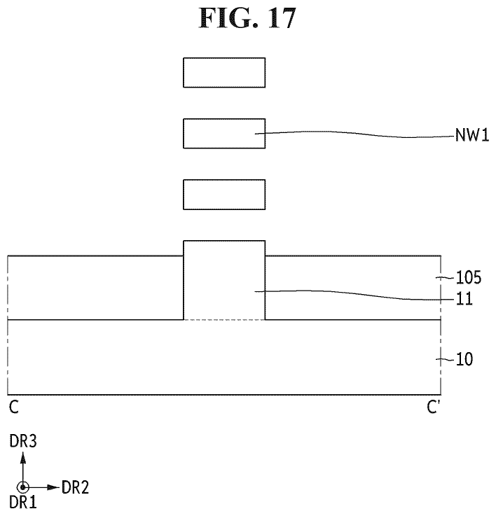

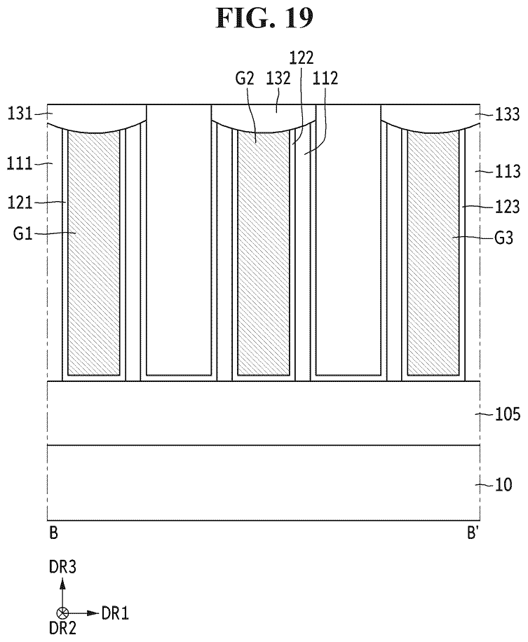

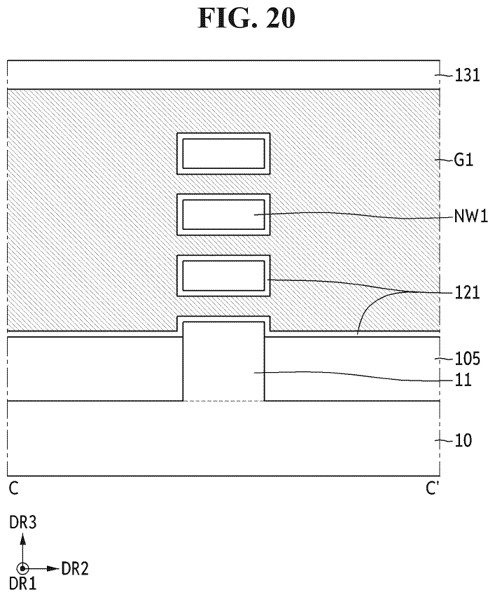

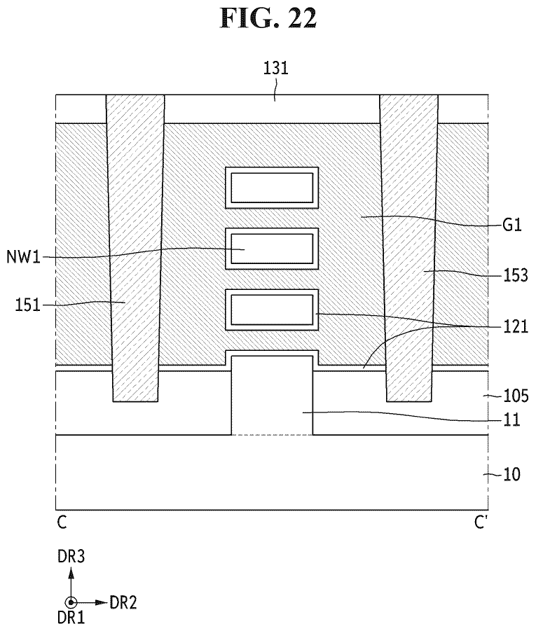

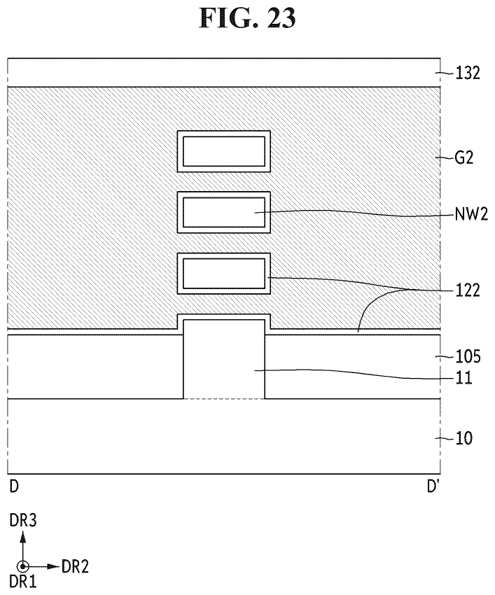

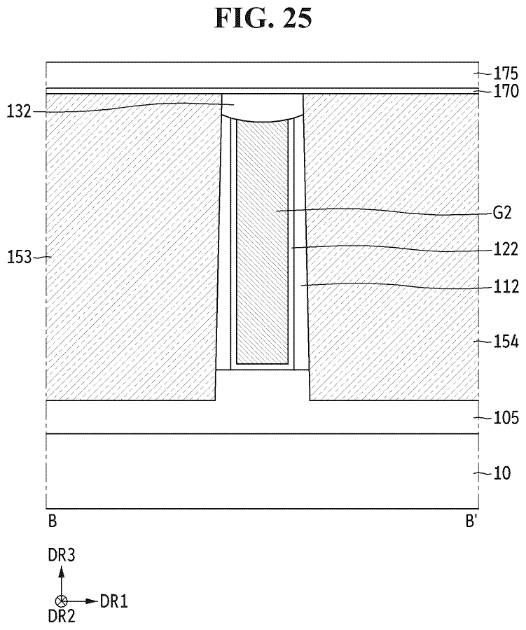

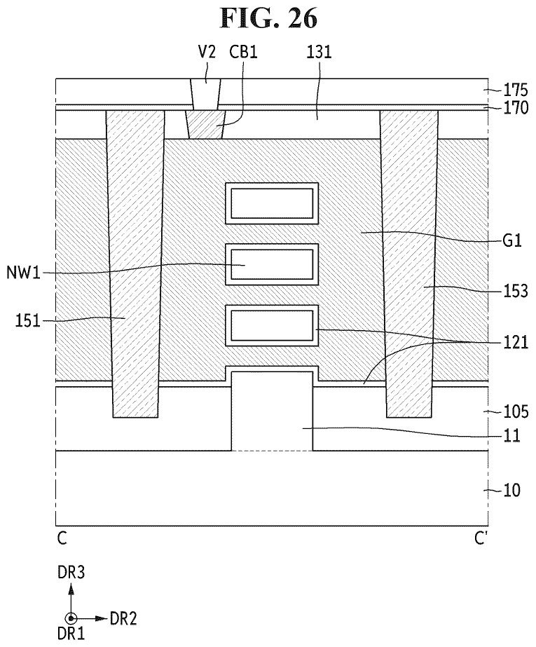

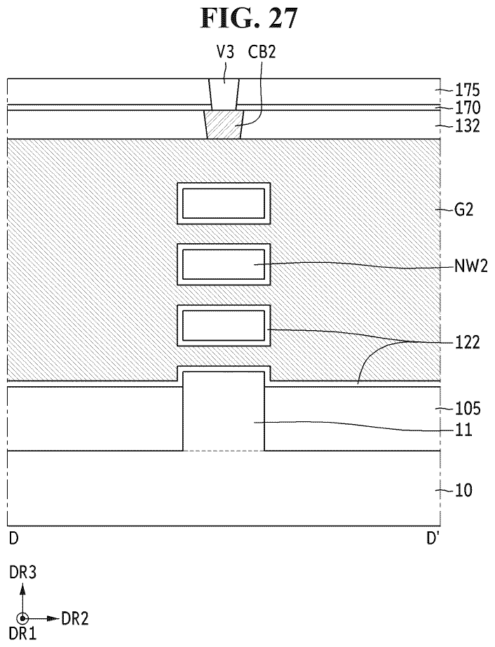

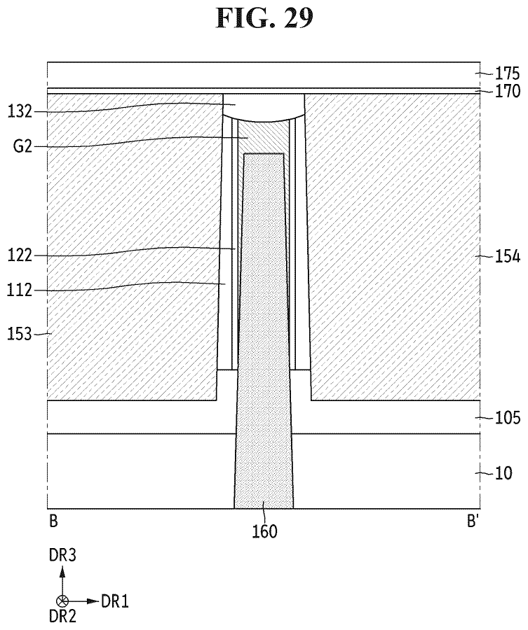

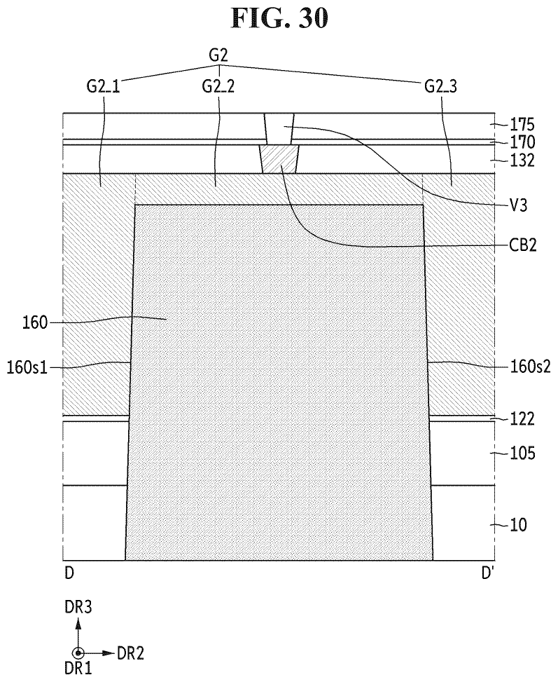

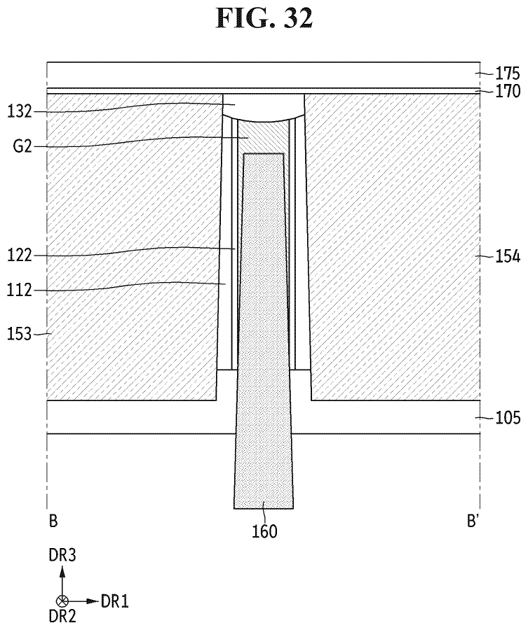

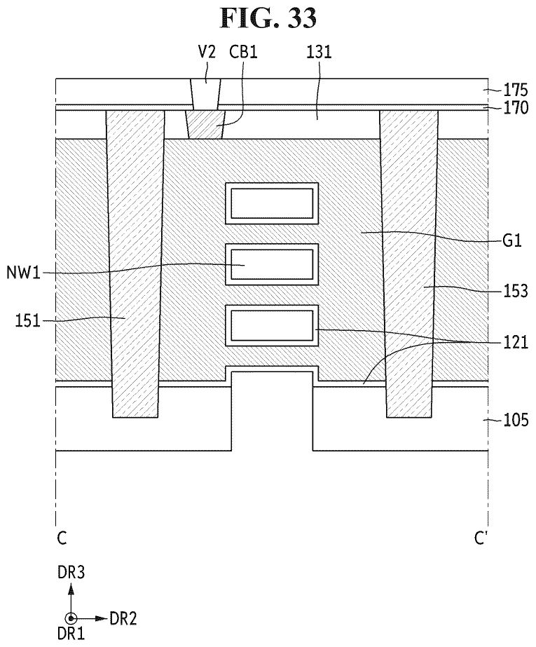

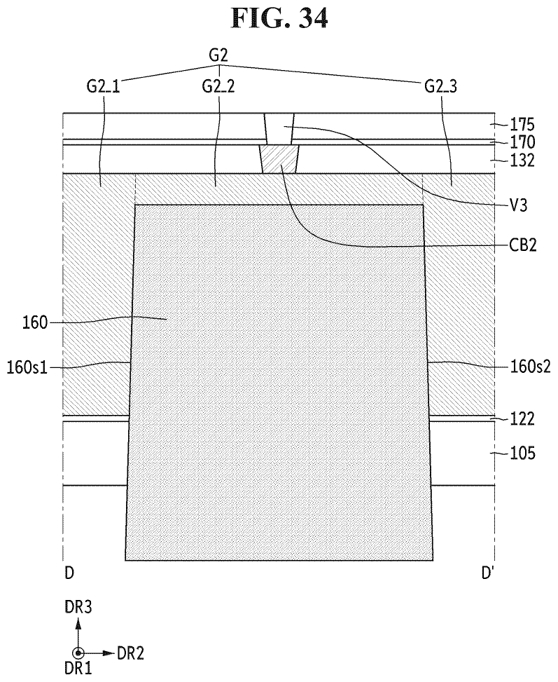

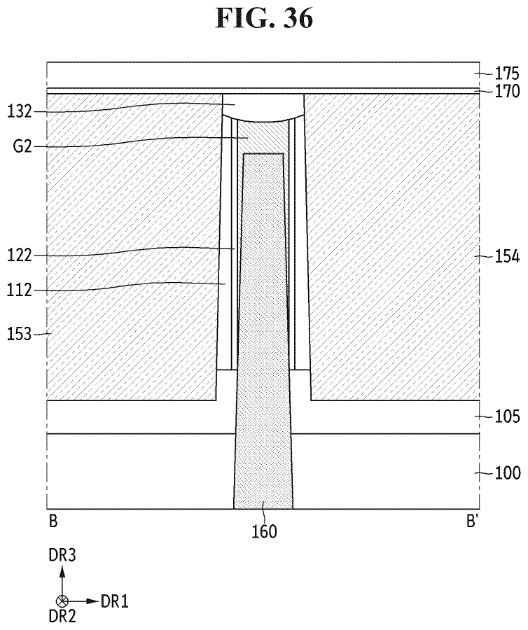

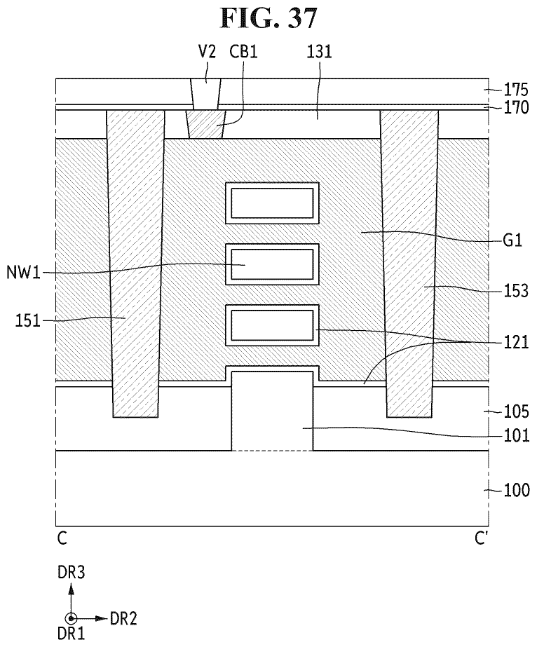

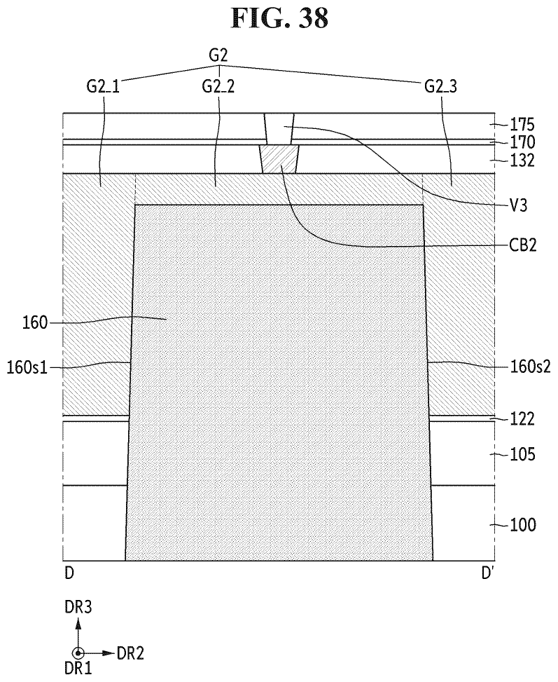

Hereinafter, the fabrication method of the semiconductor device according to some embodiments of the present disclosure will be described with reference to FIGS. 2 to 39.

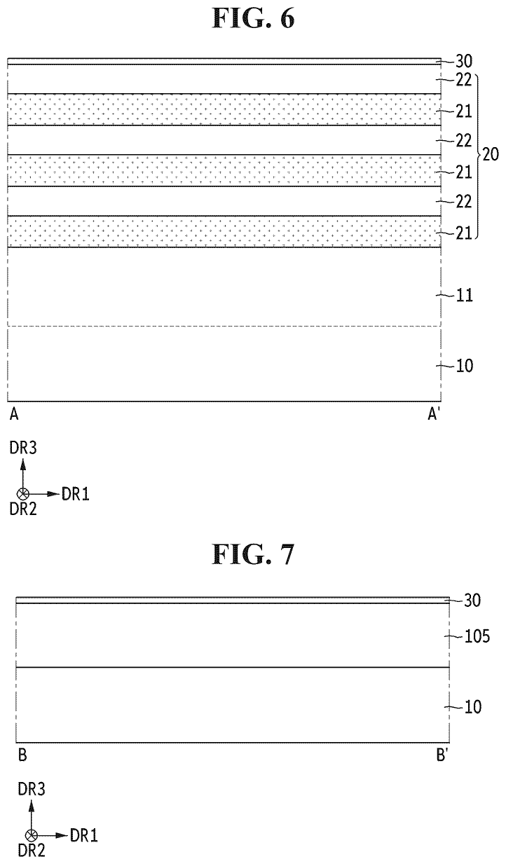

FIGS. 6 to 39 are intermediate stage diagrams for explaining the fabrication method of the semiconductor device according to some embodiments of the present disclosure.

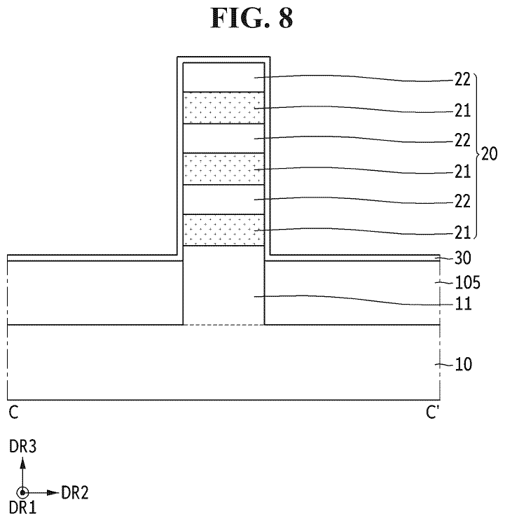

Referring to FIGS. 6 and 8, the substrate 10 may be a silicon substrate or SOI (silicon-on-insulator). Alternatively, the substrate 10 may include silicon germanium, SGOI (silicon germanium on insulator), indium antimonide, lead tellurium compound, indium arsenide, indium phosphide, gallium arsenide, or gallium antimonide. However, the present disclosure is not limited thereto.

A stacked structure 20 may be formed on the upper surface of the substrate 10. The stacked structure 20 may include a first semiconductor layer 21 and a second semiconductor layer 22 alternately stacked on the upper surface of the substrate 10. For example, the first semiconductor layer 21 may be formed at the lowermost portion of the stacked structure 20, and the second semiconductor layer 22 may be formed at the uppermost portion of the stacked structure 20. However, the present disclosure is not limited thereto. In some other embodiments, the first semiconductor layer 21 may also be formed at the uppermost portion of the stacked structure 20. The first semiconductor layer 21 may include, for example, silicon germanium (SiGe). The second semiconductor layer 22 may include, for example, silicon (Si).

A portion of the stacked structure 20 may be etched. While the stacked structure 20 is being etched, a portion of the substrate 10 may also be etched. Through this etching process, an active pattern 11 may be defined beneath the stacked structure 20 on the upper surface of the substrate 10. The active pattern 11 may protrude in the vertical direction DR3 from the upper surface of the substrate 10. The active pattern 11 may extend in the first horizontal direction DR1.

A field insulating layer 105 may be formed on the upper surface of the substrate 10. The field insulating layer 105 may surround the sidewalls of the active pattern 11. For example, the upper surface of the active pattern 11 may be formed higher than the upper surface of the field insulating layer 105. Then, a pad oxide layer 30 may be formed to cover the upper surface of the field insulating layer 105, the exposed sidewalls of the active pattern 11, and the sidewalls and upper surface of the stacked structure 20. For example, the pad oxide layer 30 may be formed conformally. The pad oxide layer 30 may include, for example, silicon oxide (SiO₂).

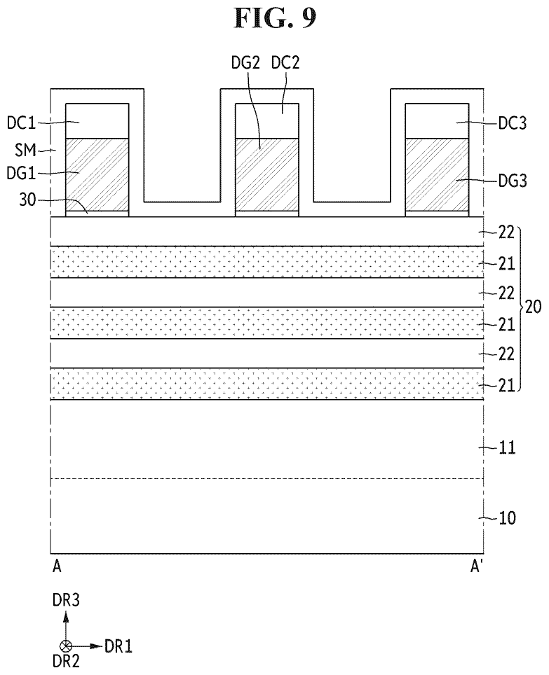

Referring to FIGS. 9 to 11, the first to third dummy gates DG1, DG2, DG3 and the first to third dummy capping patterns DC1, DC2, DC3, which extend in the second horizontal direction DR2, may be formed on the pad oxide layer 30 over the stacked structure 20 and the field insulating layer 105. Specifically, the second dummy gate DG2 may be spaced apart from the first dummy gate DG1 in the first horizontal direction DR1. The third dummy gate DG3 may be spaced apart from the second dummy gate DG2 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3. While the first to third dummy gates DG1, DG2, DG3 and the first to third dummy capping patterns DC1, DC2, DC3 are being formed, the remaining pad oxide layer 30 may be etched except for the portion that overlaps with each of the first to third dummy gates DG1, DG2, DG3 in the vertical direction DR3 on the substrate 10.

A spacer material layer SM may be formed to cover the sidewalls of each of the first to third dummy gates DG1, DG2, DG3, the sidewalls and upper surfaces of each of the first to third dummy capping patterns DC1, DC2, DC3, the exposed sidewalls and upper surface of the stacked structure 20, and the upper surface of the field insulating layer 105. For example, the spacer material layer SM may be conformally formed. The spacer material layer SM may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and/or combinations thereof.

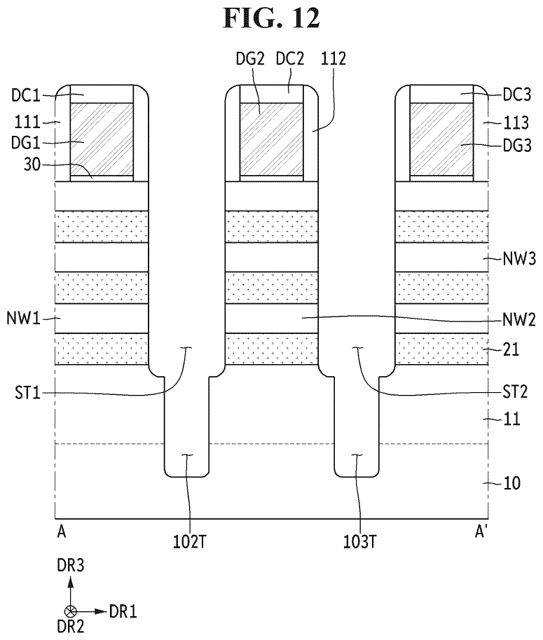

Referring to FIG. 12, the stacked structure 20 (see FIG. 9) and the active pattern 11 may be etched using the first to third dummy gates DG1, DG2, DG3 and the first to third dummy capping patterns DC1, DC2, DC3 as masks to form first and second source/drain trenches ST1, ST2. The first source/drain trench ST1 may be formed between the first dummy gate DG1 and the second dummy gate DG2. The second source/drain trench ST2 may be formed between the second dummy gate DG2 and the third dummy gate DG3.

Additionally, a first sacrificial pattern trench 102T may be formed beneath the first source/drain trench ST1, and a second sacrificial pattern trench 103T may be formed beneath the second source/drain trench ST2. For example, each of the first and second sacrificial pattern trenches 102T, 103T may penetrate the active pattern 11 in the vertical direction DR3 to be extended into the inside of the substrate 10. In other words, the bottom surfaces of each of the first and second sacrificial pattern trenches 102T, 103T may be defined by the substrate 10. For example, the width of each of the first and second sacrificial pattern trenches 102T, 103T in the first horizontal direction DR1 may be smaller than the width of each of the first and second source/drain trenches ST1, ST2 in the first horizontal direction DR1, but the present disclosure is not limited thereto.

For example, while the first and second source/drain trenches ST1, ST2 and the first and second sacrificial pattern trenches 102T, 103T are being formed respectively, a portion of the spacer material layer SM (see FIG. 9) formed on the upper surface of each of the first to third dummy capping patterns DC1, DC2, DC3 and a portion of each of the first to third dummy capping patterns DC1, DC2, DC3 may be etched. The spacer material layer SM (see FIG. 9) remaining on the sidewalls of each of the first to third dummy capping patterns (DC1, DC2, DC3) and the first to third dummy gates DG1, DG2, DG3 may be defined as the first to third gate spacers 111, 112, 113.

For example, after the first and second source/drain trenches ST1, ST2 and the first and second sacrificial pattern trenches 102T, 103T are formed respectively, the second semiconductor layer 22 (see FIG. 9) remaining beneath the first dummy gate DG1 on the active pattern 11 may be defined as the first plurality of nanosheets NW1. After the first and second source/drain trenches ST1, ST2 and the first and second sacrificial pattern trenches 102T, 103T are formed respectively, the second semiconductor layer 22 (see FIG. 9) remaining beneath the second dummy gate DG2 on the active pattern 11 may be defined as the second plurality of nanosheets NW2. After the first and second source/drain trenches ST1, ST2 and the first and second sacrificial pattern trenches 102T, 103T are formed respectively, the second semiconductor layer 22 (see FIG. 9) remaining beneath the third dummy gate DG3 on the active pattern 11 may be defined as the third plurality of nanosheets NW3.

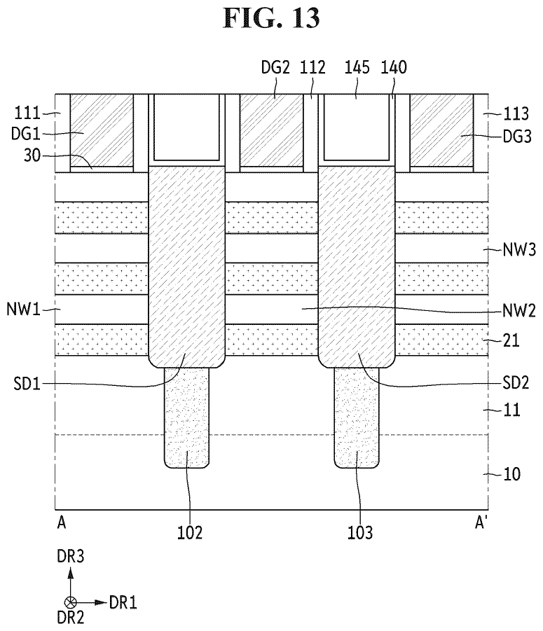

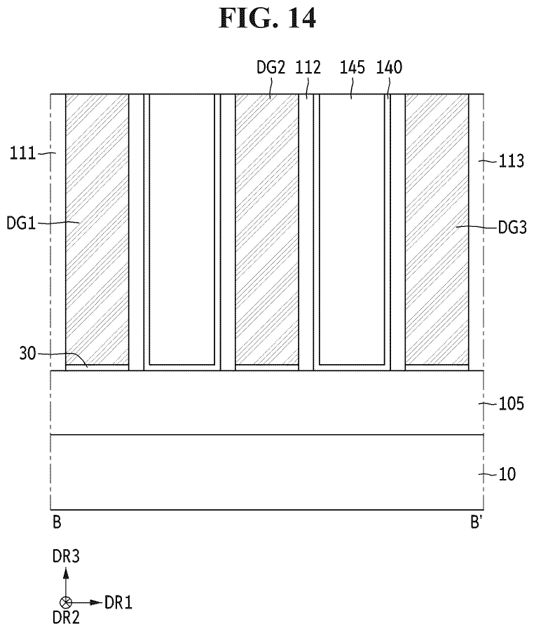

Referring to FIGS. 13 and 14, the first sacrificial pattern 102 may be formed inside the first sacrificial pattern trench 102T (see FIG. 12). Additionally, the second sacrificial pattern 103 may be formed inside the second sacrificial pattern trench 103T (see FIG. 12). For example, the upper surfaces of each of the first and second sacrificial patterns 102, 103 may be formed lower than the uppermost surface of the active pattern 11. For example, the sidewalls of each of the first and second sacrificial patterns 102, 103 in the first horizontal direction DR1 may be in contact with the active pattern 11 and the substrate 10. The bottom surface of each of the first and second sacrificial patterns 102, 103 may be in contact with the substrate 10. For example, each of the first and second sacrificial patterns 102, 103 may include silicon germanium (SiGe).

The first source/drain region SD1 may be formed inside the first source/drain trench ST1 (see FIG. 12). For example, the bottom surface of the first source/drain region SD1 may be in contact with the first sacrificial pattern 102. For example, the first source/drain region SD1 may be in contact with the sidewalls of each of the first and second plurality of nanosheets NW1, NW2 in the first horizontal direction DR1. Additionally, the second source/drain region SD2 may be formed inside the second source/drain trench ST2 (see FIG. 12). For example, the bottom surface of the second source/drain region SD2 may be in contact with the second sacrificial pattern 103. For example, the second source/drain region SD2 may be in contact with the sidewalls of each of the second and third plurality of nanosheets NW2, NW3 in the first horizontal direction DR1.

The first etching stop layer 140 may be formed on the sidewalls of each of the exposed first to third gate spacers 111, 112, 113, the upper surfaces of each of the exposed first and third dummy capping patterns DC1, DC2, DC3 (see FIG. 12), and the surfaces of each of the exposed first and second source/drain regions SD1, SD2. The first upper interlayer insulating layer 145 may be formed on the first etching stop layer 140. Then, the upper surfaces of each of the first to third dummy gates DG1, DG2, DG3 may be exposed through a planarization process.

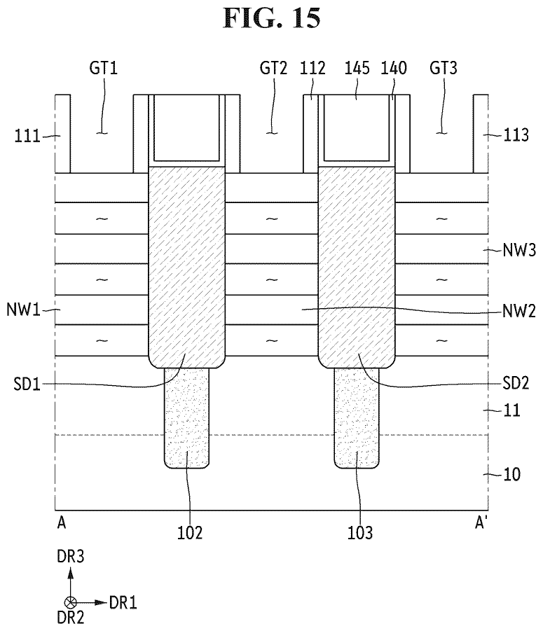

Referring to FIGS. 15 to 17, each of the first to third dummy gates DG1, DG2, DG3 (see FIGS. 13 and 14), the pad oxide layer 30 (see FIGS. 13 and 14), and the first semiconductor layer 21 (see FIG. 13) may be etched. For example, the portion where the first dummy gate DG1 (see FIGS. 13 and 14), the pad oxide layer 30 (see FIGS. 13 and 14), and the first semiconductor layer 21 (see FIG. 13) are removed may be defined as the first gate trench GT1. The portion where the second dummy gate DG2 (see FIGS. 13 and 14), the pad oxide layer 30 (see FIGS. 13 and 14), and the first semiconductor layer 21 (see FIG. 13) are removed may be defined as the second gate trench GT2. The portion where the third dummy gate DG3 (see FIGS. 13 and 14), the pad oxide layer 30 (see FIGS. 13 and 14), and the first semiconductor layer 21 (see FIG. 13) are removed may be defined as the third gate trench GT3.

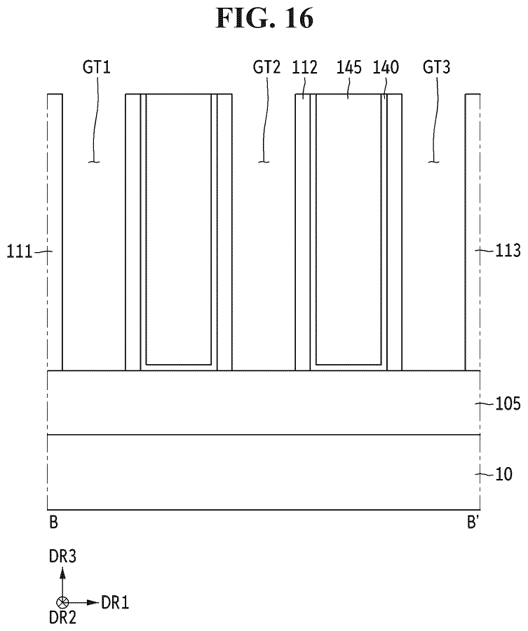

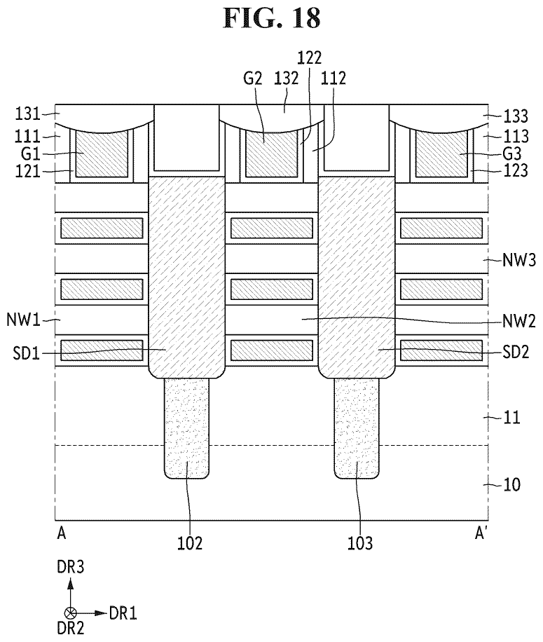

Referring to FIGS. 18 to 20, the first gate insulating layer 121, the first gate electrode G1, and the first capping pattern 131 may each be formed sequentially inside the first gate trench GT1 (see FIGS. 15 and 16). Additionally, the second gate insulating layer 122, the second gate electrode G2, and the second capping pattern 132 may each be formed sequentially inside the second gate trench GT2 (see FIGS. 15 and 16). Further, the third gate insulating layer 123, the third gate electrode G3, and the third capping pattern 133 may each be formed sequentially inside the third gate trench GT3 (see FIGS. 15 and 16). For example, the first gate electrode G1 may surround the first plurality of nanosheets NW1. The second gate electrode G2 may surround the second plurality of nanosheets NW2. The third gate electrode G3 may surround the third plurality of nanosheets NW3.

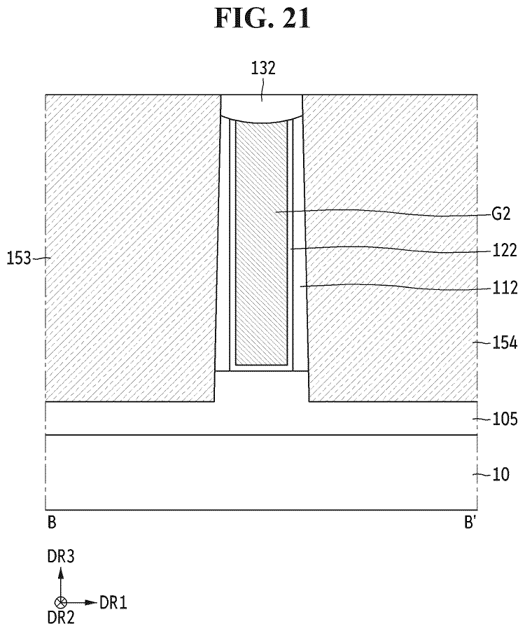

Referring to FIG. 1, FIG. 21 to FIG. 23, the first and second gate cuts 151, 152 may be formed on the first sidewall of the active pattern 11. Additionally, the third and fourth gate cuts 153, 154 may be formed on the second sidewall of the active pattern 11, which opposes the first sidewall of the active pattern 11 in the second horizontal direction DR2. For example, the second gate cut 152 may be spaced apart from the first gate cut 151 in the first horizontal direction DR1. The fourth gate cut 154 may be spaced apart from the third gate cut 153 in the first horizontal direction DR1. For example, each of the first to fourth gate cuts 151, 152, 153, 154 does not intersect with the second gate electrode G2. That is, each of the first to fourth gate cuts 151, 152, 153, 154 is not in contact with the second gate electrode G2.

For example, each of the first to fourth gate cuts 151, 152, 153, 154 may be in contact with the second gate spacer 112 and the second capping pattern 132. For example, each of the first and third gate cuts 151, 153 may separate the first gate electrode G1 in the second horizontal direction DR2. Additionally, each of the second and fourth gate cuts 152, 154 may separate the third gate electrode G3 in the second horizontal direction DR2. For example, the bottom surfaces of each of the first to fourth gate cuts 151, 152, 153, 154 may be formed inside the field insulating layer 105. For example, the upper surfaces of each of the first to fourth gate cuts 151, 152, 153, 154 may be formed on the same plane as the upper surfaces of each of the first to third capping patterns 131, 132, 133.

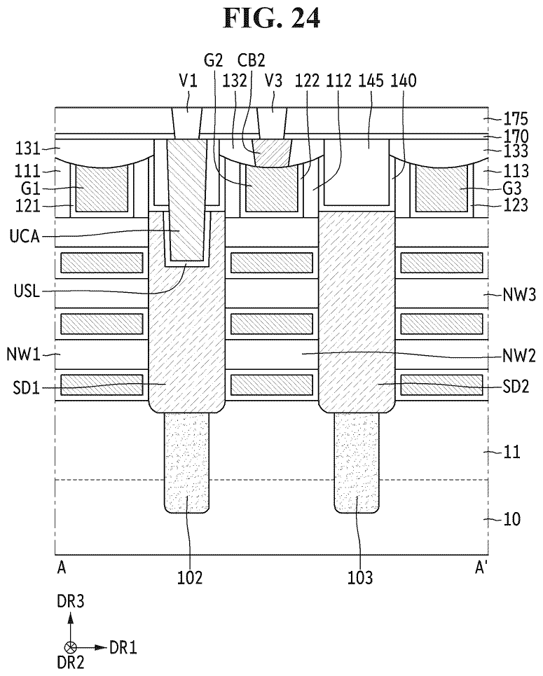

Referring to FIGS. 24 to 27, the upper source/drain contact UCA may be formed on the first source/drain region SD1. The upper source/drain contact UCA may penetrate the first upper interlayer insulating layer 145 and the first etching stop layer 140 in the vertical direction DR3 to be extended into the inside of the first source/drain region SD1. The upper silicide layer USL may be formed between the first source/drain region SD1 and the upper source/drain contact UCA. Additionally, the first gate contact CB1 may be formed which penetrates the first capping pattern 131 in the vertical direction DR3 and is connected to the first gate electrode G1. The second gate contact CB2 may be formed which penetrates the second capping pattern 132 in the vertical direction DR3 and is connected to the second gate electrode G2.

The second etching stop layer 170 and the second upper interlayer insulating layer 175 may be formed sequentially on the upper surfaces of each of the first upper interlayer insulating layer 145, the first to third capping patterns 131, 132, 133, the first and second gate contacts CB1, CB2, the first to fourth gate cuts 151, 152, 153, 154, and the upper source/drain contact UCA. Each of the first to third vias V1, V2, V3 may be formed inside the second etching stop layer 170 and the second upper interlayer insulating layer 175.

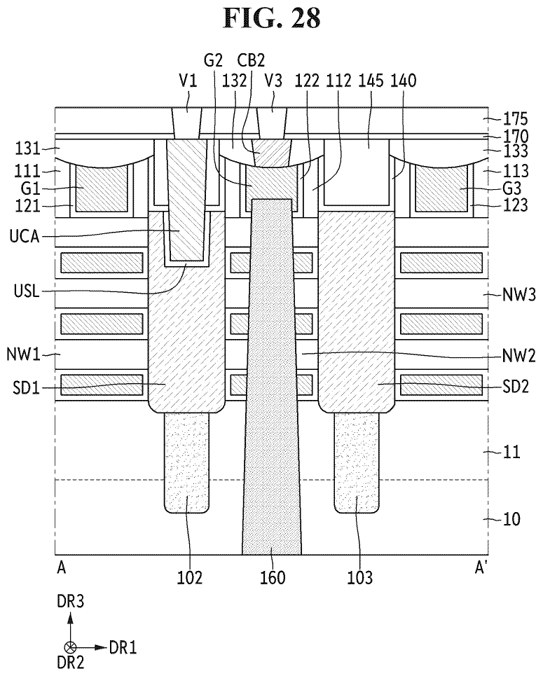

Referring to FIGS. 28 to 30, the active cut 160 may be formed beneath the second gate electrode G2. The active cut 160 may extend in the second horizontal direction DR2. For example, the active cut 160 may penetrate the substrate 10, the active pattern 11, the field insulating layer 105, and the second plurality of nanosheets NW2 in the vertical direction DR3. For example, the upper surface of the active cut 160 may be formed higher than the upper surface of the uppermost nanosheet of the second plurality of nanosheets NW2, relative to the substrate 10. For example, the upper surface of the active cut 160 may be in contact with the second gate electrode G2. For example, the portion being in contact with the first sidewall 160s1 of the active cut 160 may be defined as the first portion G2_1 of the second gate electrode G2, the portion being in contact with the upper surface of the active cut 160 may be defined as the second portion G2_2 of the second gate electrode G2, and the portion being in contact with the second sidewall 160s2 of the active cut 160 may be defined as the third portion G2_3 of the second gate electrode G2.

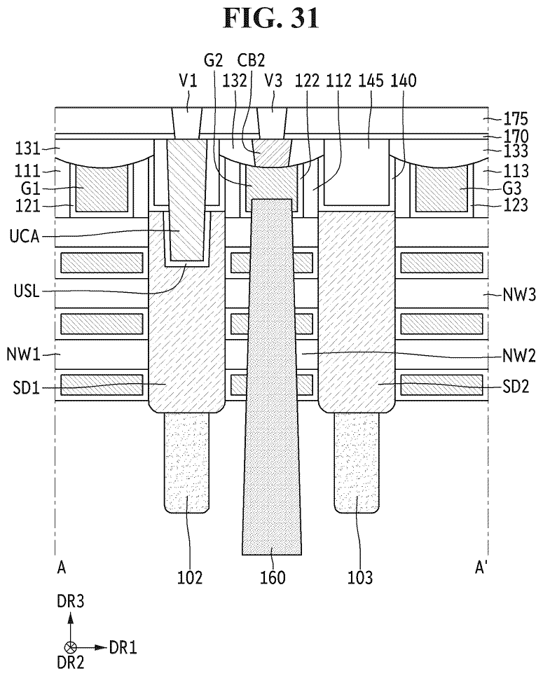

Referring to FIGS. 31 to 34, the substrate 10 (see FIGS. 28 to 30) and the active pattern 11 (see FIG. 28) may be etched.

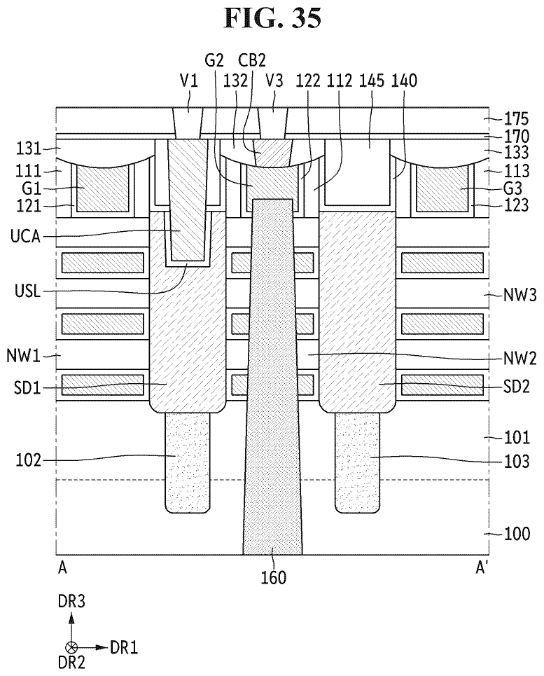

Referring to FIGS. 35 to 38, the lower interlayer insulating layer 100 and the insulating pattern 101 may be formed on the portions where the substrate 10 (see FIGS. 28 to 30) and the active pattern 11 (see FIG. 28) are each etched. For example, the insulating pattern 101 may be formed on the portion where the active pattern 11 (see FIG. 28) is etched. Also, the lower interlayer insulating layer 100 may be formed on the portion where the substrate 10 (see FIGS. 28 to 30) is etched. A planarization process may be performed to expose the bottom surface of the active cut 160.

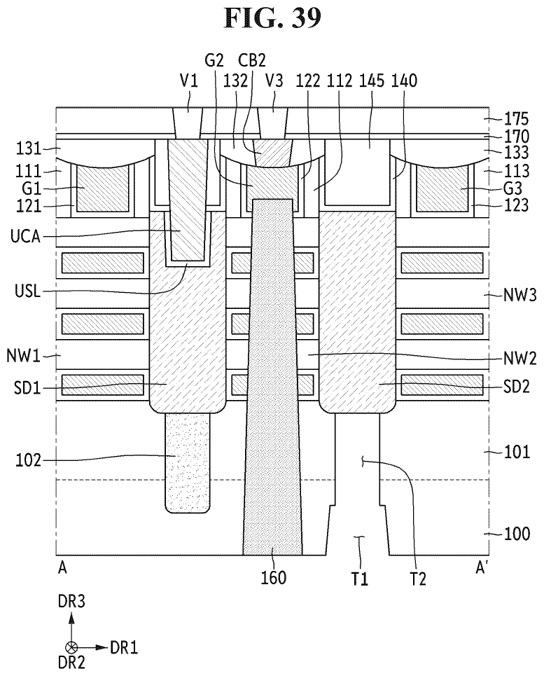

Referring to FIG. 39, the first contact trench T1 may be formed inside the lower interlayer insulating layer 100 beneath the second source/drain region SD2. The second sacrificial pattern 103 (see FIG. 35) may be exposed through the first contact trench T1. The second sacrificial pattern 103 (see FIG. 35) may be etched through the first contact trench T1. The portion in which the second sacrificial pattern 103 (see FIG. 35) is etched may be defined as the second contact trench T2. The second source/drain region SD2 may be exposed through the second contact trench T2.

Referring to FIGS. 2 to 5, the bottom source/drain contact BCA may be formed inside each of the first contact trench T1 and the second contact trench T2. Further, the bottom silicide layer BSL may be formed between the bottom source/drain contact BCA and the second source/drain region SD2. Through this fabrication process, the semiconductor device shown in FIGS. 2 to 5 may be fabricated.

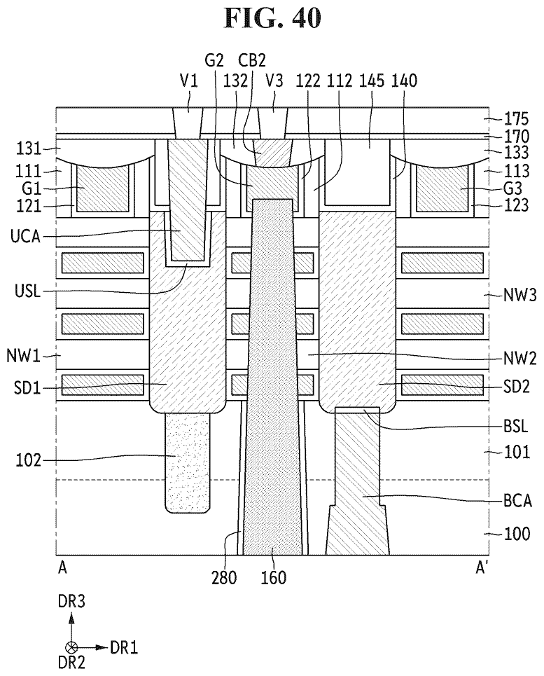

Hereinafter, the semiconductor device according to some other embodiments of the present disclosure will be described with reference to FIG. 40. The description will focus on the differences from the semiconductor device shown in FIGS. 1 to 5.

FIG. 40 is a cross-sectional view for explaining the semiconductor device according to some other embodiments of the present disclosure.

Referring to FIG. 40, in the semiconductor device according to some other embodiments of the present disclosure, a liner layer 280 may be disposed on the sidewalls of the active cut 160 in the first horizontal direction DR1.

For example, the liner layer 280 may be disposed between each of the lower interlayer insulating layer 100 and insulating pattern 101 and the sidewalls of the active cut 160 in the first horizontal direction DR1. Although not shown, the liner layer 280 may be disposed between each of the lower interlayer insulating layer 100 and the field insulating layer 105 and the sidewalls of the active cut 160 in the second horizontal direction DR2. For example, the liner layer 280 may be conformally formed. For example, the upper surface of the liner layer 280 may be in contact with the second gate insulating layer 122. For example, the bottom surface of the liner layer 280 may be formed on the same plane as the bottom surface of the active cut 160.

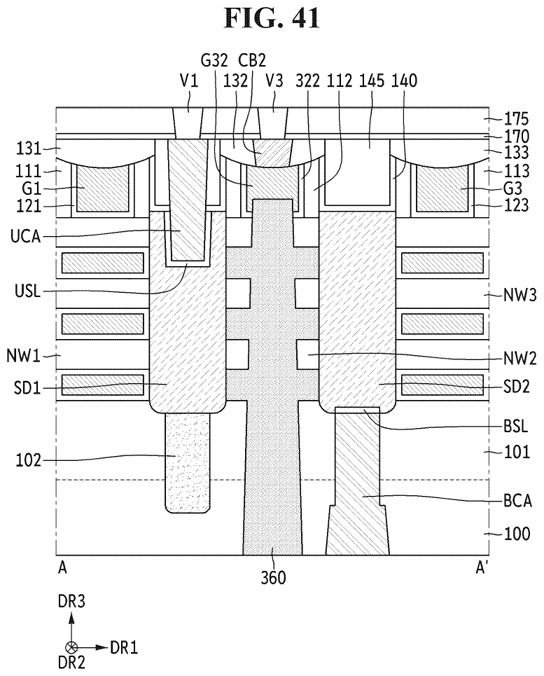

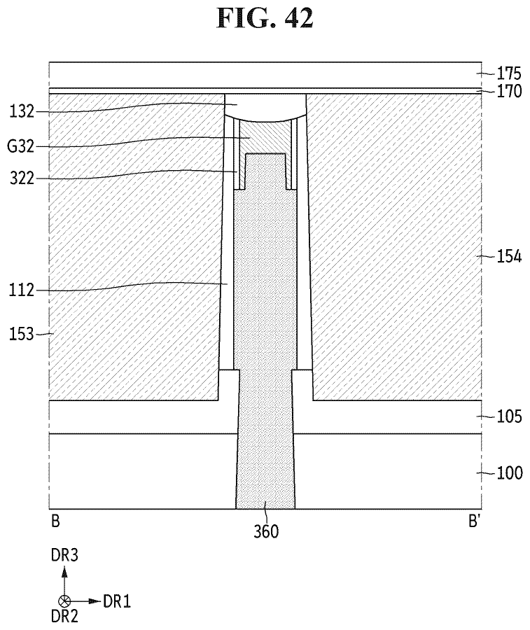

Hereinafter, with reference to FIGS. 41 and 42, semiconductor devices in accordance with some other embodiments of the present disclosure will be described. The description will focus on the differences from the semiconductor device shown in FIGS. 1 to 5.

FIGS. 41 and 42 are cross-sectional views for explaining the semiconductor device according to another several embodiments of the present disclosure.

Referring to FIGS. 41 and 42, in the semiconductor device according to another several embodiments of the present disclosure, opposing first and second sidewalls of the active cut 360 in the first horizontal direction DR1 may be in contact with the first and second source/drain regions SD1, SD2, respectively.

For example, between the upper surface of the insulating pattern 101 and the bottom surface of the lowermost nanosheet of the second plurality of nanosheets NW2, first and second sidewalls of the active cut 360 in the first horizontal direction DR1 may be in contact with the first and second source/drain regions SD1, SD2, respectively. Additionally, between adjacent ones of the second plurality of nanosheets NW2, first and second sidewalls of the active cut 360 in the first horizontal direction DR1 may be in contact with the first and second source/drain regions SD1, SD2, respectively. For example, at least a portion of the opposing sidewalls of the active cut 360 in the second horizontal direction DR2 may be in contact with the second gate spacer 112. For example, between the active cut 360 and the second gate spacer 112, the bottom surface of the second gate insulating layer 322 and the bottom surface of the second gate electrode G32 may each be in contact with the active cut 360.

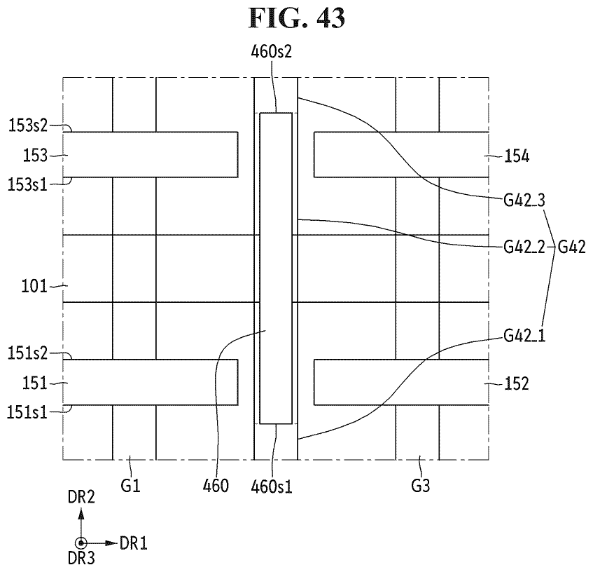

Hereinafter, the semiconductor device according to some other embodiments of the present disclosure will be described with reference to FIG. 43. The description will focus on the differences from the semiconductor device shown in FIGS. 1 to 5.

FIG. 43 is a layout diagram for explaining the semiconductor device according to another several embodiments of the present disclosure.

Referring to FIG. 43, in the semiconductor device according to another several embodiments of the present disclosure, the second sidewall 460s2 of the active cut 460 may protrude in the second horizontal direction DR2 beyond the second sidewall 153s2 of the third gate cut 153. Further, the first sidewall 460s1 of the active cut 460 may oppositely protrude in the second horizontal direction DR2 beyond the first sidewall 151s1 of the first gate cut 151.

For example, the second portion G42_2 of the second gate electrode G42 may overlap with each of the first to fourth gate cuts 151, 152, 153, 154 in the first horizontal direction DR1. For example, the first portion G42_1 of the second gate electrode G42 may not overlap with any of the first to fourth gate cuts 151, 152, 153, 154 in the first horizontal direction DR1. Additionally, the third portion G42_3 of the second gate electrode G42 may not overlap with any of the first to fourth gate cuts 151, 152, 153, 154 in the first horizontal direction DR1.

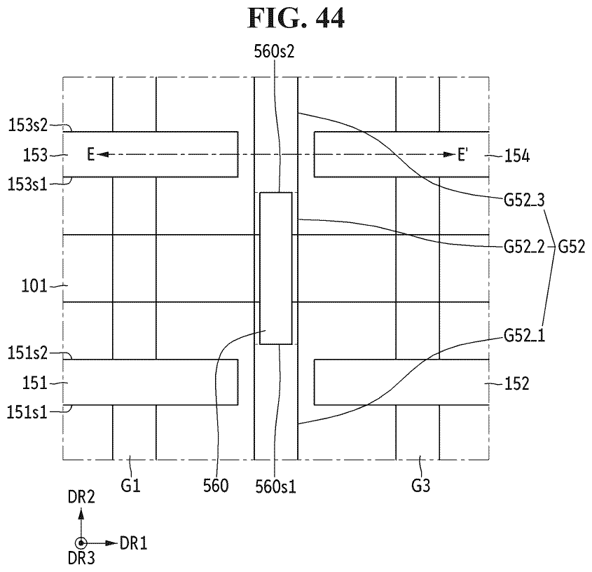

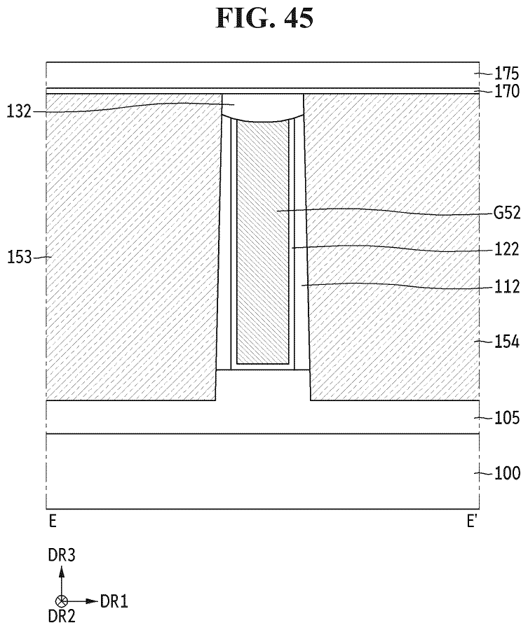

Hereinafter, the semiconductor device according to some other embodiments of the present disclosure will be described with reference to FIGS. 44 and 45. The description will focus on the differences from the semiconductor device shown in FIGS. 1 to 5.

FIG. 44 is a layout diagram for explaining the semiconductor device according to another several embodiments of the present disclosure. FIG. 45 is a cross-sectional view taken along the line E-E′ of FIG. 44.

Referring to FIGS. 44 and 45, in the semiconductor device according to some other embodiments of the present disclosure, the active cut 560 may not overlap with any of the first to fourth gate cuts 151, 152, 153, 154 in the first horizontal direction DR1.

For example, the first sidewall 560s1 of the active cut 560 may be formed closer to the insulating pattern 101 than the second sidewall 151s2 of the first gate cut 151. Additionally, the second sidewall 560s2 of the active cut 560 may be formed closer to the insulating pattern 101 than the first sidewall 153s1 of the third gate cut 153. For example, the first portion G52_1 of the second gate electrode G52 may overlap with each of the first and second gate cuts 151, 152 in the first horizontal direction DR1. The third portion G52_3 of the second gate electrode G52 may overlap with each of the third and fourth gate cuts 153, 154 in the first horizontal direction DR1. For example, the second portion G52_2 of the second gate electrode G52 may not overlap with each of the first to fourth gate cuts 151, 152, 153, 154 in the first horizontal direction DR1.

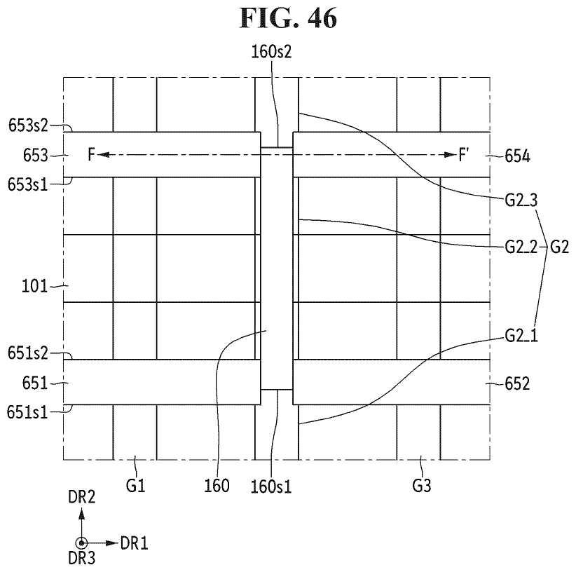

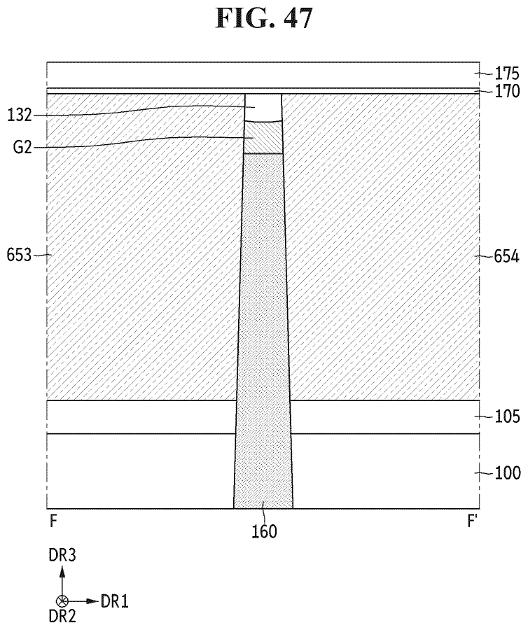

Hereinafter, the semiconductor device according to some other embodiments of the present disclosure will be described with reference to FIGS. 46 and 47. The description will focus on the differences from the semiconductor device shown in FIGS. 1 to 5.

FIG. 46 is a layout diagram for explaining the semiconductor device according to another several embodiments of the present disclosure. FIG. 47 is a cross-sectional view taken along the line F-F′ of FIG. 46.

Referring to FIG. 46 and FIG. 47, in the semiconductor device according to some other embodiments of the present disclosure, opposing sidewalls of the active cut 160 in the first horizontal direction DR1 may be in contact with each of the first to fourth gate cuts 651, 652, 653, 654.

For example, the first sidewall 160s1 of the active cut 160 may be formed between the first sidewall 651s1 of the first gate cut 651 and the second sidewall 651s2 of the first gate cut 651. The second sidewall 160s2 of the active cut 160 may be formed between the first sidewall 653s1 of the third gate cut 653 and the second sidewall 653s2 of the third gate cut 653. For example, the sidewalls in the first horizontal direction DR1 of each of the third gate cut 653 and the fourth gate cut 654 may be in contact with each of the active cut 160, the second gate electrode G2, and the second capping pattern 132. Although not shown, the sidewalls in the first horizontal direction DR1 of each of the first gate cut 651 and the second gate cut 652 may be in contact with each of the active cut 160, the second gate electrode G2, and the second capping pattern 132.

While embodiments according to the present disclosure have been described above with reference to the accompanying drawings, it will be understood that the present disclosure is not limited to the above embodiments and may be fabricated in a variety of different forms, and those of ordinary skill in the art to which the present disclosure belongs, may recognize that it may be implemented in other specific forms without changing the technical idea of the present disclosure. Therefore, it should be understood that the above-described embodiments are by way of example in all respects and not restrictive.

What is claimed is:

1. A semiconductor device comprising:
a lower interlayer insulating layer;
an insulating pattern on the lower interlayer insulating layer and extending in a first direction that is parallel to an upper surface of the lower interlayer insulating layer and crosses a second direction that is parallel to the upper surface of the lower interlayer insulating layer;
a plurality of nanosheets stacked on the insulating pattern and spaced apart from each other in a third direction that is perpendicular to the upper surface of the lower interlayer insulating layer;
an active cut penetrating the lower interlayer insulating layer, the insulating pattern and the plurality of nanosheets in the third direction, the active cut extending in the second direction and comprising an upper surface extending between opposing first and second sidewalls; and
a first gate electrode extending in the second direction on the insulating pattern, the first gate electrode at least partially surrounding the plurality of nanosheets,
wherein the first gate electrode comprises:
a first portion in contact with the first sidewall of the active cut in the second direction;
a second portion in contact with the upper surface of the active cut, the second portion at least partially surrounding the plurality of nanosheets; and
a third portion in contact with the second sidewall of the active cut in the second direction, and
wherein the second portion of the first gate electrode connects the first portion of the first gate electrode and the third portion of the first gate electrode.

2. The semiconductor device of claim 1, further comprising:
a second gate electrode extending in the second direction on the insulating pattern, the second gate electrode on a first side of the first gate electrode in the first direction;
a third gate electrode extending in the second direction on the insulating pattern, the third gate electrode on a second side of the first gate electrode opposite the first side of first gate electrode in the first direction;
a first gate cut extending in the first direction on the lower interlayer insulating layer, the first gate cut spaced apart from the insulating pattern in the second direction, the first gate cut penetrating the second gate electrode in the second direction; and
a second gate cut extending in the first direction on the lower interlayer insulating layer, the second gate cut spaced apart from the insulating pattern in the second direction, the second gate cut spaced apart from the first gate cut in the first direction, the second gate cut penetrating the third gate electrode in the second direction.

3. The semiconductor device of claim 2, wherein at least a portion of the active cut is between the first gate cut and the second gate cut in the first direction.

4. The semiconductor device of claim 2, wherein the second sidewall of the active cut, which is opposite the first sidewall in the second direction, overlaps with each of the first and second gate cuts in the first direction.

5. The semiconductor device of claim 2, wherein the second sidewall of the active cut, which is opposite the first sidewall in the second direction, is closer to the insulating pattern than a sidewall of the first gate cut facing the insulating pattern.

6. The semiconductor device of claim 1, further comprising:
a capping pattern in contact with an upper surface of the first gate electrode, the capping pattern spaced apart from the upper surface of the active cut in the third direction.

7. The semiconductor device of claim 1, wherein the upper surface of the active cut is farther than an upper surface of an uppermost nanosheet of the plurality of nanosheets from the lower interlayer insulating layer.

8. The semiconductor device of claim 1, wherein a sidewall of the active cut in the first direction is in contact with the first gate electrode and an uppermost nanosheet of the plurality of nanosheets, relative to the lower interlayer insulating layer.

9. The semiconductor device of claim 1, further comprising:
a source/drain region on the insulating pattern and in contact with sidewalls of the plurality of nanosheets in the first direction; and
a bottom source/drain contact penetrating the lower interlayer insulating layer and the insulating pattern in the third direction, the bottom source/drain contact electrically connected to the source/drain region.

10. The semiconductor device of claim 1, wherein the active cut is between ones of the plurality of nanosheets in the first direction, and the first and second sidewalls of the active cut are in contact with the first gate electrode.

11. The semiconductor device of claim 1, further comprising:
a source/drain region on the insulating pattern and in contact with sidewalls of the plurality of nanosheets in the first direction,
wherein a portion of the active cut is between ones of the plurality of nanosheets and is in contact with the source/drain region.

12. The semiconductor device of claim 2, wherein at least a portion of the first gate electrode is between the active cut and each of the first and second gate cuts in the first direction.

13. A semiconductor device comprising:
a lower interlayer insulating layer;
an insulating pattern on the lower interlayer insulating layer and extending in a first direction that is parallel to an upper surface of the lower interlayer insulating layer;
a first gate electrode on the insulating pattern and extending in a second direction that is parallel to the upper surface of the lower interlayer insulating layer and crosses the first direction;
a second gate electrode extending in the second direction on the insulating pattern, the second gate electrode spaced apart from the first gate electrode in the first direction;
a third gate electrode extending in the second direction on the insulating pattern, the third gate electrode spaced apart from the second gate electrode in the first direction;
a first gate cut extending in the first direction on the lower interlayer insulating layer, the first gate cut spaced apart from the insulating pattern in the second direction, the first gate cut penetrating the first gate electrode in the second direction;
a second gate cut extending in the first direction on the lower interlayer insulating layer, the second gate cut spaced apart from the insulating pattern in the second direction, the second gate cut spaced apart from the first gate cut in the first direction, the second gate cut penetrating the third gate electrode in the second direction; and
an active cut penetrating the lower interlayer insulating layer and the insulating pattern in a third direction perpendicular to the upper surface of the lower interlayer insulating layer, the active cut extending in the second direction beneath the second gate electrode and comprising an upper surface extending between opposing first and second sidewalls, the upper surface of the active cut in contact with the second gate electrode, at least a portion of the active cut between the first gate cut and the second gate cut,
wherein the second gate electrode comprises:
a first portion in contact with the first sidewall of the active cut in the second direction;
a second portion in contact with the upper surface of the active cut; and,
a third portion in contact with the second sidewall of the active cut in the second direction, and
wherein the second portion of the second gate electrode connects the first portion of the second gate electrode and the third portion of the second gate electrode.

14. The semiconductor device of claim 13, further comprising:
a capping pattern in contact with an upper surface of the second gate electrode, the capping pattern spaced apart from the upper surface of the active cut in the third direction.

15. The semiconductor device of claim 13, further comprising:
a plurality of nanosheets on the insulating pattern and spaced apart from each other in the third direction, the plurality of nanosheets at least partially surrounded by the second portion of the second gate electrode.

16. The semiconductor device of claim 13, wherein the active cut is spaced apart from each of the first and second gate cuts in the first direction.

17. The semiconductor device of claim 13, further comprising:
a liner layer between the active cut and each of the lower interlayer insulating layer and the insulating pattern.

18. The semiconductor device of claim 13, wherein the first gate cut comprises a first sidewall facing the insulating pattern and a second sidewall opposite the first sidewall in the second direction, and
wherein the second sidewall of the active cut in the second direction protrudes farther in the second direction than the second sidewall of the first gate cut.

19. The semiconductor device of claim 13, wherein the first and second sidewalls of the active cut are in contact with the first and second gate cuts, respectively, in the first direction.

20. A semiconductor device comprising:
a lower interlayer insulating layer;
an insulating pattern on the lower interlayer insulating layer extending in a first direction that is parallel to an upper surface of the lower interlayer insulating layer and crosses a second direction that is parallel to the upper surface of the lower interlayer insulating layer;
a plurality of nanosheets stacked on the insulating pattern and spaced apart from each other in a third direction that is perpendicular to the upper surface of the lower interlayer insulating layer;
a first gate electrode extending in the second direction on the insulating pattern;
a second gate electrode extending in the second direction on the insulating pattern, the second gate electrode spaced apart from the first gate electrode in the first direction, the second gate electrode at least partially surrounding the plurality of nanosheets;
a third gate electrode extending in the second direction on the insulating pattern, the third gate electrode spaced apart from the second gate electrode in the first direction;
a source/drain region between the second and third gate electrodes on the insulating pattern;
a bottom source/drain contact penetrating the lower interlayer insulating layer and the insulating pattern in the third direction, the bottom source/drain contact electrically connected to the source/drain region;
a first gate cut extending in the first direction on the lower interlayer insulating layer, the first gate cut spaced apart from the insulating pattern in the second direction, the first gate cut penetrating the first gate electrode in the second direction;
a second gate cut extending in the first direction on the lower interlayer insulating layer, the second gate cut spaced apart from the insulating pattern in the second direction, the second gate cut spaced apart from the first gate cut in the first direction, the second gate cut penetrating the third gate electrode in the second direction;
an active cut penetrating the lower interlayer insulating layer, the insulating pattern and the plurality of nanosheets in the third direction, the active cut extending in the second direction beneath the second gate electrode and comprising an upper surface extending between opposing first and second sidewalls, at least a portion of the active cut between the first gate cut and the second gate cut, wherein the upper surface of the active cut is higher than an upper surface of an uppermost nanosheet of the plurality of nanosheets, relative to the lower interlayer insulating layer; and
a capping pattern in contact with an upper surface of the second gate electrode, the capping pattern spaced apart from the upper surface of the active cut in the third direction,
wherein the second gate electrode comprises:
a first portion in contact with the first sidewall of the active cut in the second direction;
a second portion in contact with the upper surface of the active cut, the second portion at least partially surrounding the plurality of nanosheets; and
a third portion in contact with the second sidewall of the active cut in the second direction, and
wherein the second portion of the second gate electrode connects the first portion of the second gate electrode and the third portion of the second gate electrode.
